(19) United States
(12) Patent Application Publication
(10) Pub. No.: US 2026/0364736 A1
(43) Pub. Date: Nov. 19, 2026

(54) MODIFIED WATER-SOLUBLE POLYSACCHARIDES HAVING DIFFERENT CATION TYPES FOR SLURRIES IN CHEMICAL MECHANICAL PLANARIZATION

(71) Applicant: Versum Materials US, LLC, Tempe, AZ (US)

(72) Inventors: Inbal Davidi, Jerusalem (IL); Gregor Larbig, Gelnhausen (DE); Xiaobo Shi, Chandler, AZ (US); Sana Ma, Carlsbad, CA (US)

(21) Appl. No.: 19/115,543

(22) PCT Filed: Aug. 30, 2023
(86) PCT No.: PCT/US2023/073132

§ 371 Date: Mar. 26, 2025

Related U.S. Application Data
(60) Provisional application No. 63/377,802, filed on Sep. 30, 2022.

(51) Int. Cl. B24B 37/04; C08B 37/08; C09G 1/02; C09K 13/06; H10P 52/40

(52) U.S. Cl. CPC B24B 37/04; C08B 37/003; C09G 1/02; C09K 13/06; H10P 52/403

(57) ABSTRACT

Synthesis of cationic-modified water-soluble polysaccharide is disclosed. The cation is pendent to the polysaccharide backbone. Chemical Mechanical Planarization (CMP) slurries comprise abrasives; activator; oxidizing agent; additive comprising cationic-modified water-soluble polysaccharide; and water. The use of the synthesized cationic-modified water-soluble polysaccharide in the CMP slurries reduces dishing and erosion in highly selective tungsten slurries.

### CROSS REFERENCE TO RELATED APPLICATIONS

This application claims priority to U.S. provisional application 63/377,802 filed on Sep. 30, 2022, the entire contents of which is incorporated herein by reference thereto for all allowable purposes.

### BACKGROUND OF THE INVENTION

The present disclosure relates to chemical mechanical planarization or polishing (“CMP”) slurries (or compositions, or formulations), polishing methods and polishing systems for carrying out chemical mechanical planarization in the production of a semiconductor device. In particular, the present disclosure relates to polishing slurries that are suitably used for polishing patterned semiconductor wafers that include metallic materials containing tungsten.

Chemical mechanical polishing or planarization (CMP) has been successfully used in the manufacturing process of integrated circuits for decades. It is considered as key and enabling technology for the downsizing demand.

Integrated circuits are interconnected through the use of well-known multilevel interconnections. Interconnection structures normally have a first layer of metallization, an interconnection layer, a second level of metallization, and typically third and subsequent levels of metallization. Interlevel dielectric materials such as silicon dioxide and sometimes low-k materials are used to electrically isolate the different levels of metallization in a silicon substrate or well. The electrical connections between different interconnection levels are made through the use of metallized vias and in particular tungsten vias. U.S. Pat. No. 4,789,648 describes a method for preparing multiple metallized layers and metallized vias in insulator films. In a similar manner, metal contacts are used to form electrical connections between interconnection levels and devices formed in a well. The metal vias and contacts are generally filled with tungsten and generally employ an adhesion layer such as titanium nitride (TiN) and/or titanium to adhere a metal layer such as a tungsten metal layer to the dielectric material.

In one semiconductor manufacturing process, metallized vias or contacts are formed by a blanket tungsten deposition followed by a CMP step. In a typical process, via holes are etched through the interlevel dielectric (ILD) to interconnection lines or to a semiconductor substrate. Next, a thin adhesion layer such as titanium nitride and/or titanium is generally formed over the ILD and is directed into the etched via hole. Then, a tungsten film is blanket deposited over the adhesion layer and into the via. The deposition is continued until the via hole is filled with tungsten. Finally, the excess tungsten is removed by CMP to form metal vias.

In another semiconductor manufacturing process, tungsten is used as a gate electrode material in the transistor because of its superior electrical characteristics over poly-silicon which has been traditionally used as gate electrode material, as taught by A. Yagishita et al, IEEE TRANSACTIONS ON ELECTRON DEVICES, VOL. 47, NO. 5, May 2000.

In a typical CMP process, the substrate is placed in direct contact with a rotating polishing pad. A carrier applies pressure against the backside of the substrate. During the polishing process, the pad and table are rotated while a downward force is maintained against the substrate back. An abrasive and chemically reactive solution, commonly referred to as a polishing “slurry”, a polishing “composition” or a polishing “formulation”, is deposited onto the pad during polishing, where rotation and/or movement of the pad relative to the wafer brings said slurry into the space between the polishing pad and the substrate surface. The slurry initiates the polishing process by chemically reacting with the film being polished. The polishing process is facilitated by the rotational movement of the pad relative to the substrate as slurry is provided to the wafer/pad interface. Polishing is continued in this manner until the desired film on the insulator is removed. Removal of tungsten in the CMP is believed to be due to synergy between mechanical abrasion and tungsten oxidation followed by dissolution.

Despite its relatively simple outward appearance, chemical mechanical planarization (CMP) is a highly complex process as described by Lee Cook in digital Encyclopedia of Applied Physics, 2019, DOI: 10.1002/3527600434.eap847; and most of the time, CMP technology evolves faster than the understanding on which it is based as described by Seo, J. in Journal of Materials Research 2021, 36 (1), 235.1.

It's importance as enabling technology for past and future requirements for device scaling and new trends in semiconductor industry is undisputed. A multitude of interactions between wafer, slurry and pad as well as general process parameters determine the CMP outcome. Finally, material removal in CMP is the result of complex interaction between chemical and mechanical forces as described by Lee, D.; Lee, H.; Jeong, H. Slurry components in metal chemical mechanical planarization (CMP) process: A review. International Journal of Precision Engineering and Manufacturing 2016, 17, 1751. Large numbers of materials are used in semiconductor device fabrication, all of which require an optimized CMP process. Simultaneous polishing of combinations of completely different materials such as dielectric materials, barrier and metal layers is a real challenge with CMP.

One of the commonly encountered problems in CMP in particular in metal applications such as tungsten is how to control topological defects such as erosion and dishing. Smaller feature sizes and devices at the 7 nm node and beyond impose even stricter requirements on the acceptable extent of defects during polishing.

Highly selective slurries, which have a large difference in removal rate of metal versus rate of dielectric removal, are of great interest for future industry needs. However, there are imperfections associated with the use of these highly selective slurries. Metal layers can easily be over-polished, creating a “dishing” effect. Another unacceptable defect is called “erosion”, which describes topographical difference between an area with dielectric and a dense array of metal vias or trenches.

Specially designed water-based slurries are considered main drivers in improving CMP performance for future devices. The slurry developments not only affect the removal rate and selectivity between different layers, but also control defects during the polishing process. In general, the slurry composition is a complex combination of abrasives and chemical ingredients with different functions. As dispersants, passivation agents or generally as a topography-controlling additive, polymer additives play a key role in the slurry development to obtain the desired removal rates, selectivity and minimize surface imperfections by interacting with certain materials. For example, positively charged polymers inhibit tungsten removal and can be used to reduce dishing effects in tungsten CMP processes.

U.S. Pat. No. 5,876,490 describes the use of polish slurry comprising abrasive particles and exhibiting normal stress effect and further comprising polyelectrolyte having ionic moieties of a charge that differs from that associated with said abrasive particles and wherein the concentration of said polyelectrolyte is about 5 to about 50 percent by weight of said abrasive particles and wherein said polyelectrolyte has a molecular weight of about 500 to about 10,000.

US 2010/0075501 A1 describes a chemical mechanical polishing aqueous dispersion used to polish a polishing target that includes an interconnect layer that contains tungsten. The chemical mechanical polishing aqueous dispersion includes: (A) a cationic water-soluble polymer; (B) an iron (III) compound; and (C) colloidal silica particles. The content (M_{A}) (mass %) of the cationic water-soluble polymer (A) and the content (M_{B}) (mass %) of the iron (III) compound (B) satisfy the relationship “M_{A}/M_{B}=0.004 to 0.1”. The chemical mechanical polishing aqueous dispersion has a pH of 1 to 3.

US 2010/0252774 A1 describes a chemical mechanical polishing aqueous dispersion used to polish a polishing target that includes a wiring layer that contains tungsten. The chemical mechanical polishing aqueous dispersion includes: (A) a cationic water-soluble polymer; (B) an iron (III) compound; and (C) colloidal silica having an average particle diameter calculated from a specific surface area determined by the BET method of 10 to 60 nm. The content (M_{A}) (mass %) of the cationic water-soluble polymer (A) and the content (M_{C}) (mass %) of colloidal silica (C) satisfy the relationship “M_{A}/M_{C}=0.0001 to 0.003”. the chemical mechanical polishing aqueous dispersion.

U.S. Pat. No. 10,604,678 B1 discloses a process and a composition for polishing tungsten containing select quaternary phosphonium compounds at low concentrations to at least reduce corrosion rate of tungsten. The process and composition include providing a substrate containing tungsten, providing a stable polishing composition, containing, as initial components: water, an oxidizing agent: select quaternary phosphonium compounds at low concentrations to at least reduce corrosion rate: a dicarboxylic acid. a source of iron ions: a colloidal silica abrasive and optionally a pH adjusting agent; providing a chemical mechanical polishing pad, having a polishing surface; creating dynamic contact at an interface between the polishing pad and the substrate; and dispensing the polishing composition onto the polishing surface at or near the interface between the polishing pad and the substrate; wherein some of the tungsten is polished away from the substrate, and corrosion rate of tungsten is reduced.

US 2009/0081871 A1 discloses a method comprising chemically-mechanically polishing a substrate with an inventive polishing composition comprising a liquid carrier, a cationic polymer, an acid, and abrasive particles that have been treated with an aminosilane compound.

US 2014/0248823 A1 describes a chemical-mechanical polishing composition containing (a) abrasive particles, (b) a polymer, and (c) water, wherein (i) the polymer possesses an overall charge, (ii) the abrasive particles have a zeta potential Za measured in the absence of the polymer and the abrasive particles have a zeta potential Zb measured in the presence of the polymer, wherein the zeta potential Za is a numerical value that is the same sign as the overall charge of the polymer, and (iii) Izeta potential Zbl>Izeta potential Zal. The invention also provides a method of polishing a substrate with the polishing composition.

In general, the polyelectrolytes described essentially contain nitrogen-containing cations of the ammonium type. Cationic polymers of the imidazolium-type, polyionic liquids based on phosphonium groups, and triazole- or triazolium-based polymers have been identified and used in the CMP slurries in U.S. provisional applications 63/191,047 filed on May 20, 2021; 63/209,306 filed on Jun. 10, 2021; and 63/251,127 filed on Oct. 1, 2021, respectively; which are entirely incorporated herein by reference.

One of the commonly encountered problems in CMP, particularly in metal applications such as tungsten, is dishing of tungsten lines and erosion of arrays of metal lines. Dishing and erosion are critical CMP parameters that define the planarity of the polished wafers. Dishing of lines typically increases for wider lines. Erosion of arrays typically increases with an increase in pattern density.

Tungsten CMP slurries must be formulated such that the dishing and erosion can be minimized in order to meet certain design targets critical for a functioning device.

Finding solutions to control topological defects such as erosion and dishing is key to future CMP requirements. There still has been a need for novel tungsten CMP slurries that can reduce dishing and erosion while maintain desirable removal rate in polishing.

### BRIEF SUMMARY OF THE INVENTION

The present invention satisfies the need by providing intelligent designed tungsten CMP slurries, systems, and methods of using the CMP slurries to minimize the described problem of dishing and erosion in highly selective tungsten slurries while maintain desirable polishing of metal layers, specifically tungsten films.

More specifically, the present invention discloses the tailored cationic-modified water-soluble polysaccharides where the cation is pendent to the water-soluble polysaccharide backbone; the synthesis of the cationic-modified water-soluble polysaccharides; and the use of the cationic-modified water-soluble polysaccharides in the slurries of CMP. A variety of functional groups can be attached to the water-soluble polysaccharide backbone (from bulky groups to less steric hindering groups) to fine-tune the polymer performance and properties.

Several specific aspects of the present invention are outlined below.
Aspect 1: A cationic-modified water-soluble polysaccharide comprises cationic repeating unit having a structure selected from the group consisting of:

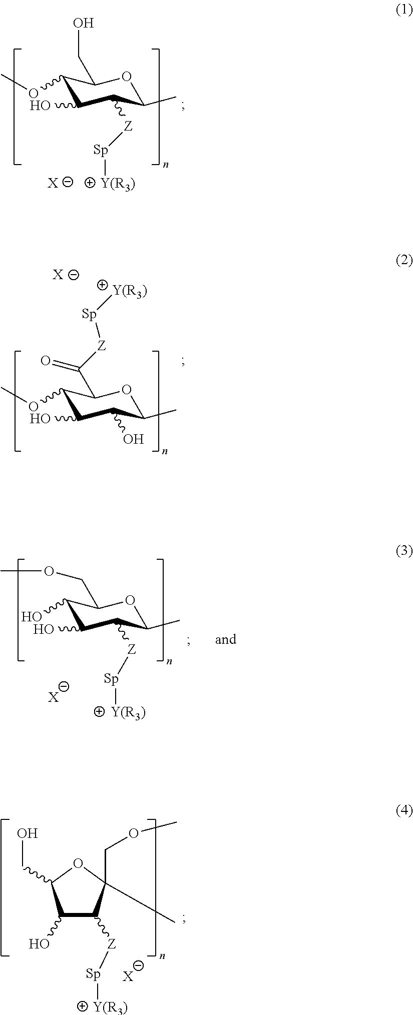

wherein
the water-soluble polysaccharide is selected from the group consisting of chitosan, pectin, dextran, pullulan, and inulin;
pentagon or hexagon denotes the backbone of the water-soluble polysaccharide;
Z is selected from the group consisting of NH, —O—, —S—, —O—(C═O)—, —NH—(C═O)—, —O—(C═O)—, —NH—(C═O)—, NR′ wherein R′ is alkyl having C₁ to C₆, and carbon to carbon double-bonds, or triple-bond as shown below:

—HC═CH—

—R″C═CH—

R″C═CR″—

R″C═CR′″—

—C≡C—
wherein two carbon atoms in the double bond structure can be connected to two protons, or one proton and one alkyl group R″ wherein R″ is alkyl having C₁ to C₆, or two same alkyl groups R″, or two different alkyl groups R″ and R′″ wherein R′″ is alkyl having C₁ to C₆;
preferably Z denotes NH or —O—;
Sp denotes at each occurrence a spacer group having a single bond or double bond structure; preferably single bond structure;
Y⁺ denotes a cation function such as N⁺, P⁺, S⁺;
X⁻ denotes the counter ion which can be halide (F⁻, Cl⁻, Br⁻, I⁻), BF₄⁻, CF₃BF₃⁻, OH⁻, PF₆⁻, carboxylate, malonate, citrate, carbonate, fumarate, MeOSO₃⁻, MeSO₃⁻, CF₃COO⁻, CF₃SO₃⁻, cyanate, isothiocyanate, nitrate, phosphate or sulfate, wherein Me is methyl;
R denotes a cation side group selected from the group consisting of H, CH₃, alkyl chains (saturated or unsaturated, branched or aliphatic), cyclic ring such as phenyl ring, and other functional groups such as amine, carboxylic acid, sulfonates, siloxanes, ethers, alcohols, another cation, and other side group; wherein (R)₃ can be alkyl or form a ring selected from the group consisting of imidazolium, triazolium, and tetrazolium; tris-alkyl phosphonium, tris-phenyl phosphonium, tris-alkyl sulfonium, tris-phenyl sulfonium;
n denotes the number of the repeating units, wherein 1<n<2000, 50<n<1500, or 75<n<1000.
Aspect 2: The cationic-modified water-soluble polysaccharide according to Aspect 1, wherein the water-soluble polysaccharide is modified by a method selected from the group consisting of etherification; esterification; amidation; and amination.
Aspect 3: The cationic-modified water-soluble polysaccharide according to Aspects 1-2, wherein an ion density (ions on the backbone) is between 5-200%, between 5%-150%, or between 10%-100%.
Aspect 4: The cationic-modified water-soluble polysaccharide according to Aspects 1-3, wherein the cationic-modified water-soluble polysaccharide is selected from the group consisting of chitosan-triphenylphosphonium bromide salt, dextran-triphenylphosphonium bromide salt, chitosan-imidazolium chloride salt, dextran-(2-hydroxy) propyl-triphenylphosphonium chloride salt, pectin-ethylene diamine triphenylphosphonium bromide salt, chitosan-trialkylphosphonium bromide salt, dextran-trialkylphosphonium bromide salt, pectin-ethylene diamine triphenylphosphonium bromide salt, chitosan-ethylene guanidinium bromide salt, dextran-imidazolium chloride salt, dextran-ethylene guanidinium bromide salt, chitosan-triazolium iodide salt, dextran-triazolium iodide salt, chitosan-guanidinium-triazolium salt, dextran-phosphonium-triazolium iodide salt, chitosan-trialkylphosphonium/triphenylphosphonium mix bromide, dextran-trialkylphosphonium/triphenylphosphonium mix bromide.
Aspect 5: A chemical mechanical planarization composition comprises the cationic-modified water-soluble polysaccharide according to Aspects 1 to 4.
Aspect 6: A chemical mechanical planarization composition comprises:
   an abrasive selected from the group consisting of inorganic oxide particles, metal oxide-coated inorganic oxide particles, organic polymer particles, metal oxide-coated organic polymer particles, and combinations thereof;
   the cationic-modified water-soluble polysaccharide according to Aspects 1 to 4; water; and optionally
   an activator;
   an oxidizing agent;
   a corrosion inhibitor;
   a dishing reducing agent;
   a stabilizer;
   a pH adjusting agent.
Aspect 7: A system for chemical mechanical planarization, comprises:
   a semiconductor substrate comprising at least one surface containing tungsten; a polishing pad; and
   the chemical mechanical planarization composition of Aspects 5-6;
   wherein the at least one surface containing tungsten is in contact with the polishing pad and the chemical mechanical planarization composition.
Aspect 8: A polishing method for chemical mechanical planarization of a semiconductor substrate comprises at least one surface containing tungsten, comprising the steps of:
   a) contacting the at least one surface containing tungsten with a polishing pad;
   b) delivering the chemical mechanical planarization composition of Aspects 5-6;
   c) polishing the at least one surface containing tungsten with the chemical mechanical planarization composition.

The abrasive includes, but is not limited to inorganic oxide particles, metal oxide-coated inorganic oxide particles, organic polymer particles, metal oxide-coated organic polymer particles, surface modified inorganic oxide particles, and combinations thereof.

The inorganic oxide particles include but are not limited to ceria, colloidal silica, high purity colloidal silica, fumed silica, colloidal ceria, alumina, titania, zirconia particles.

The metal oxide-coated inorganic oxide particles include but are not limited to the ceria-coated inorganic oxide particles, such as, ceria-coated colloidal silica, ceria-coated high purity colloidal silica, ceria-coated alumina, ceria-coated titania, ceria-coated zirconia, or any other ceria-coated inorganic oxide particles.

The organic polymer particles include, but are not limited to, polystyrene particles, polyurethane particle, polyacrylate particles, or any other organic polymer particles.

The metal oxide-coated organic polymer particles are selected from the group consisting of ceria-coated organic polymer particles, zirconia-coated organic polymer particles.

The concentration of abrasive can range from 0.01 wt. % to 30 wt. %, the preferred is from about 0.05 wt. % to about 20 wt. %, the more preferred is from about 0.01 to about 10 wt. %, and the most preferred is from 0.1 wt. % to 2 wt. %. The weight percent is relative to the composition.

The activator includes, but is not limited to (1) inorganic oxide particle with transition metal coated onto its surface; and the transition metal is selected from the group consisting of Fe, Cu, Mn, Co, Ce, and combinations thereof; (2) soluble catalyst selected from the group consisting of iron (III) nitrate, ammonium iron (III) oxalate trihydrate, iron (III) citrate tribasic monohydrate, iron (III) acetylacetonate and ethylenediamine tetraacetic acid, iron (III) sodium salt hydrate; (3) a metal compound having multiple oxidation states selected from the group consisting of Ag, Co, Cr, Cu, Fe, Mo, Mn, Nb, Ni, Os, Pd, Ru, Sn, Ti, V; and combinations thereof.

The activator ranges from 0.00001 wt. % to 5.0 wt. %, 0.0001 wt. % to 2.0 wt. %, 0.0005 wt. % to 1.0 wt. %, or 0.001 wt. % to 0.5 wt. %.

The oxidizing agent includes but is not limited to peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, ammonium peroxymonosulfate; and non-peroxy compound selected from the group consisting of ferric nitrite, KClO₄, KBrO₄, KMnO₄.

The oxidizer concentration can range from about 0.01 wt. % to 30 wt. % while the preferred concentration of oxidizing agents is from about 0.1 wt. % to 20 wt. %, and the more preferred concentration of oxidizing agents is from about 0.5 wt. % to about 10 wt. %. The weight percent is relative to the composition.

The general amount of additive comprising phosphonium based polymers or copolymers ranges from 0.00001 wt. % to 1.0 wt. %, 0.0001 wt. % to 0.5 wt. %, 0.00025 wt. % to 0.1 wt. %, or 0.0005 wt. % to 0.05 wt. %.

Suitable pH-adjusting agents to lower the pH of the polishing composition include, but are not limited to, nitric acid, sulfuric acid, tartaric acid, succinic acid, citric acid, malic acid, malonic acid, various fatty acids, various polycarboxylic acids and mixtures thereof. Suitable pH-adjusting agents to raise the pH of the polishing composition include, but are not limited to, potassium hydroxide, sodium hydroxide, ammonia, tetraethylammonium hydroxide, ethylenediamine, piperazine, polyethyleneimine, modified polyethyleneimine, and mixtures thereof.

The pH of the slurry is between 1 and 14, preferably is between 1 and 7, more preferably is between 1 and 6, and most preferably is between 1.5 and 4.

The CMP slurries may further comprise surfactant; dispersion agent; chelating agent; film-forming anticorrosion agent; and biocide.

Other aspects, features and embodiments of the invention will be more fully apparent from the ensuing disclosure and appended claims.

The embodiments of the invention can be used alone or in combinations with each other.

### DETAILED DESCRIPTION OF THE INVENTION

The present invention satisfies the need by providing intelligent designed tungsten CMP slurries, systems, and methods of using the CMP slurries to reduce the described problem of dishing and erosion in highly selective slurries while maintain desirable polishing of metal layers, specifically tungsten films.

More specifically, the present invention discloses the tailored cationic-modified water-soluble polysaccharide where the cation is pendent to the water-soluble polysaccharide backbone, the synthesis of the cationic-modified water-soluble polysaccharides, and the use of the cationic-modified water-soluble polysaccharides in the slurries of CMP.

A variety of functional groups can be attached to the water-soluble polysaccharide backbone (from bulky groups to less steric hindering groups) to fine-tune the cationic-modified water-soluble polysaccharide performance and properties. The use of cationic-modified polysaccharides can be an advantage since some water-soluble polysaccharides are commercially available.

Surprisingly, the cationic-modified water-soluble polysaccharides have shown high selectivity, low dishing and low erosion behavior. Also, with high number of modified repeating units, the polysaccharide's solubility can be improved. This unique class of polymers can be used as topography-controlling additives and are valuable tools for designing next-generation slurries.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention. The use of the term “comprising” in the specification and the claims includes the narrower language of “consisting essentially of” and “consisting of.”

Embodiments are described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

For ease of reference, “microelectronic device” corresponds to semiconductor substrates, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

“Substantially free” is defined herein as less than 0.001 wt. %. “Substantially free” also includes 0.000 wt. %. The term “free of” means 0.000 wt. %.

As used herein, “about” is intended to correspond to +5%, preferably +2% of the stated value.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.00001 weight percent, based on the total weight of the composition in which such components are employed.

There are several specific aspects of the present invention.

One aspect is for synthesizing cationic-modified water-soluble polysaccharide by modifying the water-soluble polysaccharide by a method selected from the group consisting of etherification; esterification; amidation; and amination.

Another aspect is CMP slurries comprising abrasive, an additive comprising cationic-modified water-soluble polysaccharide, and water; optionally an oxidizing agent, an activator or catalyst, a corrosion inhibitor, a dishing reducing agent, a stabilizer, and a pH adjusting agent. The pH of the slurry is between 1 and 14, preferably is between 1 and 7, more preferably is between 1 and 6, and most preferably is between 1.5 and 4.

The CMP slurries may further comprise surfactant; dispersion agent; chelator; film-forming anticorrosion agent; biocide; and a polish enhancement agent.

Yet, another aspect is a system for chemical mechanical planarization, comprising:
a semiconductor substrate comprising at least one surface containing tungsten;
a polishing pad; and
the chemical mechanical planarization composition;
wherein the at least one surface containing tungsten is in contact with the polishing pad and the chemical mechanical planarization composition.

And, yet another aspect is a polishing method for chemical mechanical planarization of a semiconductor substrate comprising at least one surface containing tungsten, comprising the steps of:
contacting the at least one surface containing tungsten with a polishing pad;
delivering the chemical mechanical planarization composition; and
polishing the at least one surface containing tungsten with the chemical mechanical planarization composition.

The CMP slurries in the present invention comprise the polycationic polymer or copolymer.

More specifically, the CMP slurries comprise abrasive, the polycationic polymer or copolymer, an oxidizing agent, an activator or catalyst, an additive, and water; optionally a corrosion inhibitor, a dishing reducing agent, a stabilizer, and a pH adjusting agent. The pH of the slurry is between 1 and 14, preferably is between 1 and 7, more preferably is between 1 and 6, and most preferably is between 1.5 and 4.

The CMP slurries may further comprise surfactant; dispersion agent; chelator; film-forming anticorrosion agent; biocide; and a polish enhancement agent.

### Abrasive

The abrasive used in CMP slurries includes, but is not limited to inorganic oxide particles, metal oxide-coated inorganic oxide particles, organic polymer particles, metal oxide-coated organic polymer particles, surface modified abrasive particles such as cationic or anionic modified, and combinations thereof.

The abrasive used in CMP slurries can be activator-containing particles (i.e., an abrasive having an activator coating); or non-activator-containing particles.

The inorganic oxide particles include but are not limited to ceria, silica, alumina, titania, germania, spinel, an oxide or nitride of tungsten, zirconia particles, or any of the above doped with one or more other minerals or elements, and any combination thereof. The oxide abrasive may be produced by any of a variety of techniques, including sol-gel, hydrothermal, hydrolytic, plasma, pyrogenic, aerogel, fuming and precipitation techniques, and any combination thereof.

Precipitated inorganic oxide particles can be obtained by known processes by reaction of metal salts and acids or other precipitating agents. Pyrogenic metal oxide and/or metalloid oxide particles are obtained by hydrolysis of a suitable, vaporizable starting material in an oxygen/hydrogen flame. An example is pyrogenic silicon dioxide from silicon tetrachloride. The pyrogenic oxides of aluminum oxide, titanium oxide, zirconium oxide, silicon dioxide, cerium oxide, germanium oxide and vanadium oxide and chemical and physical mixtures thereof are suitable.

The metal oxide-coated inorganic oxide particles include but are not limited to the ceria-coated or alumina-coated inorganic oxide particles, such as, ceria-coated colloidal silica, alumina-coated colloidal silica, ceria-coated high purity colloidal silica, alumina-coated high purity colloidal silica, ceria-coated alumina, ceria-coated titania, alumina-coated titania, ceria-coated zirconia, alumina-coated zirconia, or any other ceria-coated or alumina-coated inorganic oxide particles.

The metal oxide-coated organic polymer particles are selected from the group consisting of ceria-coated organic polymer particles, zirconia-coated organic polymer.

The organic polymer particles include, but are not limited to, polystyrene particles, polyurethane particle, polyacrylate particles, or any other organic polymer particles.

Colloidal silica particles and high purify colloidal silica particles are the preferred abrasive particles. The silica can be any of precipitated silica, fumed silica, silica fumed, pyrogenic silica, silica doped with one or more adjutants, or any other silica-based compound.

Colloidal silica particles and high purify colloidal silica particles being used as abrasives also include the surface chemically modified silica particles through chemical coupling reactions which allow such silica particle surface bearing different chemical functional groups and possess positive or negative charges at different applied pH conditions in CMP slurries. The examples of such surface chemical modified silica particles include, but not limited to, SiO₂—R—NH₂, —SiO—R—SO₃M; wherein R can be for example, (CH₂)ₙ group with n ranged from 1 to 12, and M can be for example, sodium, potassium, or ammonium.

In an alternate embodiment the silica can be produced, for example, by a process selected from the group consisting of a sol-gel process, a hydrothermal process, a plasma process, a fuming process, a precipitation process, and any combination thereof.

The abrasive is generally in the form of an abrasive particle, and typically many abrasive particles, of one material or a combination of different materials. Generally, a suitable abrasive particle is more or less spherical and has an effective diameter of about 10 to 700 nm, about 20 to 500 nm, or about 30 to 300 nanometers (nm), although individual particle size may vary. Abrasive in the form of aggregated or agglomerated particles are preferably processed further to form individual abrasive particles.

Abrasive particles may be purified using suitable method such as ion exchange to remove metal impurities that may help improve the colloidal stability. Alternatively, high purity abrasive particles are used.

In general, the above-mentioned abrasives may be used either alone or in combination with one another. It may be advantageous to have two or more abrasive particles with different sizes or different types of abrasives be combined to obtain excellent performance.

The concentration of abrasive can range from 0.01 wt. % to 30 wt. %, the preferred is from about 0.05 wt. % to about 20 wt. %, the more preferred is from about 0.01 to about 10 wt. %, and the most preferred is from 0.1 wt. % to 2 wt. %. The weight percent is relative to the composition.

### Additive

The CMP slurries of the present invention comprise additives that are the tailored modified water-soluble polysaccharides, where the cation is pendent to the polysaccharide backbone.

Positively charged polymers are generally able to interact electrostatically with negatively charged surfaces such as negatively charged metal surface. In this application, positively charged polycations polymers can electrostatically interact with W surface which is oxidized resulting in negative charge of the surface. The use of optimized quantities and tailor-made polymers can thus greatly increase the selectivity between metal removal and the removal of oxide layers while reducing dishing effects.

At low pH values of <2.5, SiO₂ layers, as a classic standard oxide material, are by no means partially positively charged. In other words, in order to block oxide erosion at the same time as metal dishing, the polymers used require are more tailored design that goes beyond the pure cationic approach.

Surprisingly, CMP slurries using cationic-modified water-soluble polysaccharides increased the RR of W while suppressed the RR of TEOS thus greatly increased the removal selectivity of W:TEOS. Furthermore, CMP slurries using the water-soluble polysaccharides been cationic-modified with cation pendent to the polysaccharide backbone showed very low dishing. This unique class of polymers can be used as topography-controlling additives and are valuable tools for designing next-generation slurries.

The cationic-modified water-soluble polysaccharide comprises cationic monomers having a structure selected from the group consisting of:

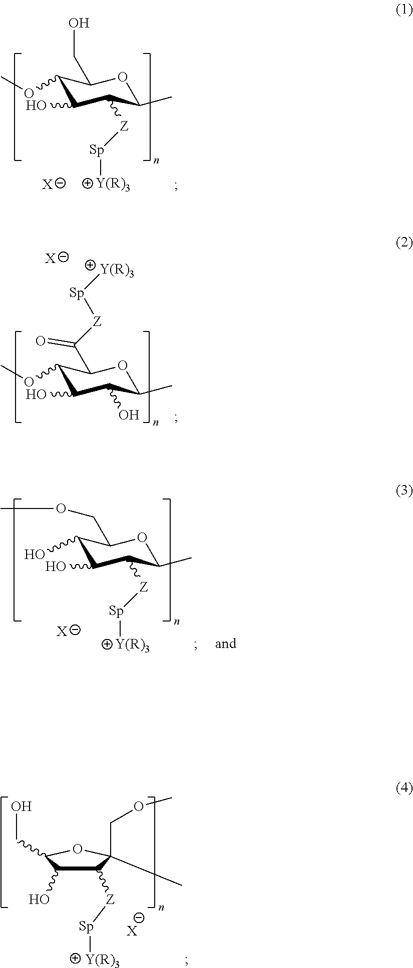

wherein
the water-soluble polysaccharide is selected from the group consisting of chitosan, pectin, dextran, pullulan, and inulin;
pentagon or hexagon denotes the backbone of the water-soluble polysaccharide;
Z is selected from the group consisting of NH—S—, —O—(C═O)—, —NH—(C═O)—, —O—(C═O)—, —NH—(C═O)—, NR′ wherein R′ is alkyl having C₁ to C₆, and carbon to carbon double-bonds, or triple-bond as shown below:

—HC═CH—

—R″C═CH—

—R″C═CR″—

—R″C═CR′″—

—C≡C—
wherein two carbon atoms in the double bond structure can be connected to two protons, or one proton and one alkyl group R″ wherein R″ is alkyl having C₁ to C₆, or two same alkyl groups R″, or two different alkyl groups R″ and R′″ wherein R′″ is alkyl having C₁ to C₆;
preferably Z denotes NH or —O—;
Sp denotes at each occurrence a spacer group having single bond or double bond structure; preferably single bond structure;
Y⁺ denotes a cation function such as N⁺, P⁺, S⁺; wherein the cationic-modified water-soluble polysaccharide comprises repeating units containing no ion, or at least one ion; such as 1 ion, 2 or 3 ions;
X⁻ denotes the counter ion which can be halide (F⁻, Cl⁻, Br⁻, I⁻), BF₄⁻, CF₃BF₃⁻, OH, PF₆⁻, carboxylate, malonate, citrate, carbonate, fumarate, MeOSO₃⁻, MeSO₃⁻, CF₃COO⁻, CF₃SO₃⁻, cyanate, isothiocyanate, nitrate, phosphate or sulfate;
R denotes a cation side group selected from the group consisting of H, CH₃, alkyl chains (saturated or unsaturated, branched or aliphatic), cyclic ring such as phenyl ring, and other functional groups such as amine, carboxylic acid, sulfonates, siloxanes, ethers, alcohols, another cation, and other side group; wherein (R) 3 be alkyl or form a ring selected from the group consisting of imidazolium, triazolium, and tetrazolium; tris-alkyl phosphonium, tris-phenyl phosphonium, tris-alkyl sulfonium, tris-phenyl sulfonium;
n denotes the number of the repeating units, wherein 1<n<2000, 50<n<1500, or 75<n<1000.

Different reactions can be performed to modify the water-soluble polysaccharide backbone. The most preferred modifications are etherification, esterification, amidation, amination or through double and triple bonds since it is stable under the polishing conditions (pH and local elevated temperatures). Other methods of modifications can be performed such as through amides, amines or any other type of bond that is stable under the polishing conditions.

The number of ions on the backbone, that is, the ion density can be changed by changing the reaction conditions so there are no, one or more than one ions on one repeating unit. Ion density can be calculated using Nuclear Magnetic Resonance (NMR), precipitation with silver nitrate, conductivity or any other analytical method. The ion density can be between 5-200%, between 5%-150%, or between 10%-100%, which is the total number of ions of the cationic-modified water-soluble polysaccharide divided by the total number of the repeating units of the water-soluble polysaccharide before being modified.

The concentration of the additive can range from 0.00001 wt. % to 1.0 wt. %, 0.0001 wt. % to 0.5 wt. %, 0.00025 wt. % to 0.1 wt. %, or 0.0005 wt. % to 0.05 wt. %. The weight percent is relative to the composition.

### Oxidizing Agent

comprise an oxidizing agent or an oxidizer for chemical etching of material.

The oxidizing agent of the CMP slurry is in a fluid composition which contacts the substrate and assists in the chemical removal of targeted material on the substrate surface. The oxidizing agent component is thus believed to enhance or increase the material removal rate of the composition. Preferably, the amount of oxidizing agent in the composition is sufficient to assist the chemical removal process, while being as low as possible to minimize handling, environmental, or similar or related issues, such as cost.

Advantageously, in one embodiment of this invention, the oxidizer is a component which will, upon exposure to at least one activator, produce free radicals giving an increased etching rate on at least selected structures. The free radicals described infra will oxidize most metals and will make the surface more susceptible to oxidation from other oxidizers. However, oxidizers are listed separately from the “Compound Producing Free Radicals”, to be discussed infra, because some oxidizers do not readily form free radicals when exposed to the activators, and in some embodiments it is advantageous to have one or more oxidizers which provide matched etching or preferential etching rates on a variety of combinations of metals which may be found on a substrate.

As is known in the art, some oxidizers are better suited for certain components than for other components. In some embodiments of this invention, the selectivity of the CMP system to one metal as opposed to another metal is maximized, as is known in the art. However, in certain embodiments of present invention, the combination of oxidizers is selected to provide substantially similar CMP rates (as opposed to simple etching rates) for a conductor and a barrier combination.

In one embodiment, the oxidizing agent is an inorganic or organic per-compound.

A per-compound is generally defined as a compound containing an element in its highest state of oxidation, such as perchloric acid; or a compound containing at least one peroxy group (—O—O—), such as peracetic acid and perchromic acid.

Suitable per-compounds containing at least one peroxy group include, but are not limited to, peracetic acid or salt thereof, a percarbonate, and an organic peroxide, such as benzoyl peroxide, urea hydrogen peroxide, and/or di-t-butyl peroxide.

Suitable per-compounds containing at least one peroxy group include peroxides. As used herein, the term “peroxides” encompasses R—O—O—R′, where R and R′ are each independently H, a C₁ to C₆ straight or branched alkyl, alkanol, carboxylic acid, ketone (for example), or amine, and each of the above can independently be substituted with one or more benzyl group (for example benzoyl peroxide) which may themselves be substituted with OH or C₁-C₅ alkyls, and salts and adducts thereof. This term therefore includes common examples such as hydrogen peroxide, peroxyformic acid, peracetic acid, propaneperoxoic acid, substituted or unsubstituted butaneperoxoic acid, hydroperoxy-acetaldehyde, also encompassed in this term are common complexes of peroxides, for example urea peroxide.

Suitable per-compounds containing at least one peroxy group include persulfates. As used herein, the term “persulfates” encompasses monopersulfates, di-persulfates, and acids and salts and adducts thereof. Included for example is peroxydisulfates, peroxymonosulfuric acid and/or peroxymonosulfates, Caro's acid, including for example a salt such as potassium peroxymonosulfate, but preferably a non-metallic salt such as ammonium peroxymonosulfate.

Suitable per-compounds containing at least one peroxy group include perphosphates, defined as above and including peroxydiphosphates.

Also, ozone is a suitable oxidizing agent either alone or in combination with one or more other suitable oxidizing agents.

Suitable per-compounds that do not contain a peroxy group include, but are not limited to, periodic acid and/or any periodiate salt (hereafter “periodates”), perchloric acid and/or any perchlorate salt (hereafter “perchlorates”) perbromic acid and/or any perbromate salt (hereafter “perbromates”), and perboric acid and/or any perborate salt (hereafter “perbromates”).

Other oxidizing agents are also suitable components of the composition of the present invention. Iodates are useful oxidizers.

Two and more oxidizers may also be combined to obtain synergistic performance benefits.

In most embodiments of the present invention, the oxidizer is selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, ammonium peroxymonosulfate; and non-per-oxy compound selected from the group consisting of ferric nitrite, KClO₄, KBrO₄, KMnO₄.

In some embodiments, the preferred oxidizer is hydrogen peroxide.

The oxidizer concentration can range from about 0.01 wt. % to 30 wt. % while the preferred concentration of oxidizing agents is from about 0.1 wt. % to 20 wt. %, and the more preferred concentration of oxidizing agents is from about 0.5 wt. % to about 10 wt. %. The weight percent is relative to the composition.

### Activator

An activator or a catalyst, is a material that interacts with an oxidizing agent and facilitates the formation of free radicals by at least one free radical-producing compounds present in the fluid.

The activator can be a metal-containing compound, in particular a metal selected from the group consisting of the metals known to activate a Fenton's Reaction process in the presence of an oxidizing agent such as, hydrogen peroxide.

The activator may be a non-metal-containing compound. Iodine is a useful with for example hydrogen peroxide to form free radicals.

If the activator is a metal ion, or metal-containing compound, it is in a thin layer associated with a surface of a solid which contacts the fluid. If the activator is a non-metal-containing substance, it can be dissolved in the fluid. It is preferred that the activator is present in amount that is sufficient to promote the desired reaction.

The activator includes, but is not limited to, (1) inorganic oxide particle with transition metal coated onto its surface, where the transition metal is selected from the group consisting of iron, copper, manganese, cobalt, cerium, and combinations thereof; (2) soluble catalyst includes, but is not limited to iron (III) nitrate, ammonium iron (III) oxalate trihydrate, iron (III) citrate tribasic monohydrate, iron (III) acetylacetonate and ethylenediamine tetraacetic acid, iron (III) sodium salt hydrate, a metal compound having multiple oxidation states selected from the group consisting of Ag, Co, Cr, Cu, Fe, Mo, Mn, Nb, Ni, Os, Pd, Ru, Sn, Ti, V; and combinations thereof.

The amount of activator in a slurry ranges from about 0.00001 wt. % to 5 wt. %, preferably about 0.0001 wt. % to 2.0 wt. %, more preferably about 0.0005 wt. % to 1.0 wt. %; and most preferably between 0.001 wt. % to 0.5 wt. %.

### Water

The polishing compositions are aqueous based and, thus, comprise water. In the compositions, water functions in various ways such as, for example, to dissolve one or more solid components of the composition, as a carrier of the components, as an aid in the removal of polishing residue, and as a diluent. Preferably, the water employed in the cleaning composition is de-ionized (DI) water.

It is believed that, for most applications, water will comprise, for example, from about 10 to about 90% by weight or 90 wt. % of water. Other preferred embodiments could comprise from about 30 to about 95 wt. % of water. Yet other preferred embodiments could comprise from about 50 to about 90 wt. % of water. Still other preferred embodiments could include water in an amount to achieve the desired weight percent of the other ingredients.

### Corrosion Inhibitor (Optional)

Corrosion inhibitors used in the CMP compositions disclosed herein include, but are not limited to, nitrogenous cyclic compounds such as 1,2,3-triazole, 1,2,4-triazole, 1,2,3-benzotriazole, 5-methylbenzotriazole, benzotriazole, 1-hydroxybenzotriazole, 4-hydroxybenzotriazole, 3-amino-1,2,4-triazole, 4-amino-4H-1,2,4-triazole, 5 amino triazole, benzimidazole, benzothiazoles such as 2,1,3-benzothiadiazole, triazinethiol, triazinedithiol, and triazinetrithiol, pyrazoles, imidazoles, isocyanurate such as 1,3,5-tris(2-hydroxyethyl), and mixtures thereof. Preferred inhibitors are 1,2,4-triazole, 5 amino triazole and 1,3,5-tris(2-hydroxyethyl) isocyanurate.

The amount of corrosion inhibitors in a slurry ranges from less than 1.0 wt. %, preferably less than 0.5 wt. %, or more preferably less than 0.25 wt. %.

### Dishing Reducing Agent (Optional)

The CMP composition may further comprise a dishing reducing agent or a dishing reducer selected from the group consisting of sarcosinate and related carboxylic compounds; hydrocarbon substituted sarcosinate; amino acids; organic polymers and copolymers having molecules containing ethylene oxide repeating units, such as polyethylene oxide (PEO); ethoxylated surfactants; nitrogen containing heterocycles without nitrogen-hydrogen bonds, sulfide, oxazolidine or mixture of functional groups in one compound; nitrogen containing compounds having three or more carbon atoms that form alkylammonium ions; amino alkyls having three or more carbon atoms; polymeric corrosion inhibitor comprising a repeating group of at least one nitrogen-containing heterocyclic ring or a tertiary or quaternary nitrogen atom; polycationic amine compound; cyclodextrin compound; polyethyleneimine compound; glycolic acid; chitosan; sugar alcohols; polysaccharides; alginate compound; sulfonic acid polymer. Glycine is a preferred dishing reducing agent.

Where the dishing reducing agent is present, the amount of dishing reducing agent ranges from about 0.001 wt. % to 2.0 wt. %, preferably 0.005 wt. % to 1.5 wt. %, and more preferably 0.01 wt. % to 1.5 wt. % based on weight per weight of the entire CMP composition.

### Stabilizers (Optional)

The composition may also include one or more of various optional additives. Suitable optional additives include stabilization agents. These optional additives are generally employed to facilitate or promote stabilization of the composition against settling, flocculation (including precipitation, aggregation or agglomeration of particles, and the like), and decomposition. Stabilizers can be used to extend the pot-life of the oxidizing agent(s), including compounds that produce free radicals, by isolating the activator material, by quenching free radicals, or by otherwise stabilizing the compounds that form free radicals.

Some materials are useful to stabilize hydrogen peroxide. One exception to the metal contamination is the presence of selected stabilizing metals such as tin. In some embodiments of this invention, tin can be present in small quantities, typically less than about 25 ppm, for example between about 3 and about 20 ppm. Similarly, zinc is often used as a stabilizer. In some embodiments of this invention, zinc can be present in small quantities, typically less than about 20 ppm, for example between about 1 and about 20 ppm. In another preferred embodiment the fluid composition contacting the substrate has less than 500 ppm, for example less than 100 ppm of dissolved metals, except for tin and zinc, having multiple oxidation states. In the most preferred commercial embodiments of this invention, the fluid composition contacting the substrate has less than 9 ppm of dissolved metals having multiple oxidation states, for example less than 2 ppm of dissolved metals having multiple oxidation states, except for tin and zinc. In some preferred embodiments of this invention, the fluid composition contacting the substrate has less than 50 ppm, preferably less than 20 ppm, and more preferably less than 10 ppm of dissolved total metals, except for tin and zinc.

As metals in solution are generally discouraged, it is preferred that those non-metal-containing oxidizers that are typically present in salt forms, for example persulfates, are in the acid form and/or in the ammonium salt form, such as ammonium persulfate.

Other stabilizers include free radical quenchers. As discussed, these will impair the utility of the free radicals produced. Therefore, it is preferred that if present they are present in small quantities. Most antioxidants, i.e., vitamin B, vitamin C, citric acid, and the like, are free radical quenchers. Most organic acids are free radical quenchers, but three that are effective and have other beneficial stabilizing properties are phosphonic acid, the binding agent oxalic acid, and the non-radical-scavenging sequestering agent gallic acid.

In addition, it is believed that carbonate and phosphate will bind onto the activator and hinder access of the fluid. Carbonate is particularly useful as it can be used to stabilize a slurry, but a small amount of acid can quickly remove the stabilizing ions. Stabilization agents useful for absorbed activator can be film forming agents forming films on the silica particle.

Suitable stabilizing agents include organic acids, such as adipic acid, phthalic acid, citric acid, malonic acid, orthophthalic acid; and phosphoric acid; substituted or unsubstituted phosphonic acids, i.e., phosphonate compounds; nitriles; and other ligands, such as those that bind the activator material and thus reduce reactions that degrade the oxidizing agent, and any combination of the foregoing agents. As used herein, an acid stabilizing agent refers to both the acid stabilizer and its conjugate base. That is, the various acid stabilizing agents may also be used in their conjugate form. By way of example, herein, an adipic acid stabilizing agent encompasses adipic acid and/or its conjugate base, a carboxylic acid stabilizing agent encompasses carboxylic acid and/or its conjugate base, carboxylate, and so on for the above-mentioned acid stabilizing agents. A suitable stabilizer, used alone or in combination with one or more other stabilizers, decreases the rate at which an oxidizing agent such as hydrogen peroxide decomposes when admixed into the CMP slurry.

On the other hand, the presence of a stabilization agent in the composition may compromise the efficacy of the activator. The amount should be adjusted to match the required stability with the lowest adverse effect on the effectiveness of the CMP system. In general, any of these optional additives should be present in an amount sufficient to substantially stabilize the composition. The necessary amount varies depending on the particular additive selected and the particular make-up of the CMP composition, such as the nature of the surface of the abrasive component. If too little of the additive is used, the additive will have little or no effect on the stability of the composition. On the other hand, if too much of the additive is used, the additive may contribute to the formation of undesirable foam and/or flocculant in the composition.

Generally, suitable amounts of these stabilizer range from about 0.0001 to 5 wt. % relative to the composition, preferably from about 0.00025 to 2 wt. %, and more preferably from about 0.0005 to about 1 wt. %. The stabilizer may be added directly to the composition or applied to the surface of the abrasive component of the composition.

### pH Adjusting Agent (Optional)

Compositions disclosed herein comprise pH adjusting agents. A pH adjusting agent is typically employed in the compositions disclosed herein to raise or lower the pH of the polishing composition. The pH-adjusting agent may be used to improve the stability of the polishing composition, to tune the ionic strength of the polishing composition, and to improve the safety in handling and use, as needed.

Suitable pH-adjusting agents to lower the pH of the polishing composition include, but are not limited to, nitric acid, sulfuric acid, tartaric acid, succinic acid, citric acid, malic acid, malonic acid, various fatty acids, various polycarboxylic acids and mixtures thereof. Suitable pH-adjusting agents to raise the pH of the polishing composition include, but are not limited to, potassium hydroxide, sodium hydroxide, ammonia, tetraethylammonium hydroxide, ethylenediamine, piperazine, polyethyleneimine, modified polyethyleneimine, and mixtures thereof.

When employed, the amount of pH-adjusting agent preferably ranges from about 0.01 wt. % to about 5.0 wt. % relative to the total weight of the polishing composition. The preferred range is from about 0.01 wt. % to about 1 wt. % or from about 0.05 wt. % to about 0.15 wt. %.

The pH of the slurry is between 1 and 14, preferably is between 1 and 7, more preferably is between 1 and 6, and most preferably is between 1.5 and 4.

### Surfactant (Optional)

The compositions disclosed herein optionally comprise a surfactant, which, in part, aids in protecting the wafer surface during and after polishing to reduce defects in the wafer surface. Surfactants may also be used to control the removal rates of some of the films used in polishing such as low-k dielectrics. Suitable surfactants include non-ionic surfactants, anionic surfactants, cationic surfactants, ampholytic surfactants, and mixtures thereof.

Non-ionic surfactants may be chosen from a range of chemical types including but not limited to long chain alcohols, ethoxylated alcohols, ethoxylated acetylenic diol surfactants, polyethylene glycol alkyl ethers, propylene glycol alkyl ethers, glucoside alkyl ethers, polyethylene glycol octylphenyl ethers, polyethylene glycol alkylphenyl ethers, glycerol alkyl esters, polyoxyethylene glycol sorbiton alkyl esters, sorbiton alkyl esters, cocamide monoethanol amine, cocamide diethanol amine dodecyl dimethylamine oxide, block-copolymers of polyethylene glycol and polypropylene glycol, polyethoxylated tallow amines, fluorosurfactants.

The molecular weight of surfactants may range from several hundreds to over 1 million. The viscosities of these materials also possess a very broad distribution.

Anionic surfactants include, but are not limited to salts with suitable hydrophobic tails, such as alkyl carboxylate, alkyl polyacrylic salt, alkyl sulfate, alkyl phosphate, alkyl bicarboxylate, alkyl bisulfate, alkyl biphosphate, such as alkoxy carboxylate, alkoxy sulfate, alkoxy phosphate, alkoxy bicarboxylate, alkoxy bisulfate, alkoxy biphosphate, such as substituted aryl carboxylate, substituted aryl sulfate, substituted aryl phosphate, substituted aryl bicarboxylate, substituted aryl bisulfate, and substituted aryl biphosphate etc. The counter ions for this type of surfactants include, but are not limited to potassium, ammonium and other positive ions. The molecular weights of these anionic surface wetting agents range from several hundred to several hundred-thousand.

Cationic surfactants possess the positive net charge on major part of molecular frame. Cationic surfactants are typically halides of molecules comprising hydrophobic chain and cationic charge centers such as amines, quaternary ammonium, benzalkonium, and alkylpyridinium ions.

In another aspect, the surfactant can be an ampholytic surfactant, which possess both positive (cationic) and negative (anionic) charges on the main molecular chains and with their relative counter ions. The cationic part is based on primary, secondary, or tertiary amines or quaternary ammonium cations. The anionic part can be more variable and include sulfonates, as in the sultaines CHAPS (3-[(3-Cholamidopropyl)dimethylammonio]-1-propanesulfonate) and cocamidopropyl hydroxysultaine. Betaines such as cocamidopropyl betaine have a carboxylate with the ammonium. Some of the ampholytic surfactants may have a phosphate anion with an amine or ammonium, such as the phospholipids phosphatidylserine, phosphatidylethanolamine, phosphatidylcholine, and sphingomyelins.

Examples of surfactants also include, but are not limited to, dodecyl sulfate sodium salt, sodium lauryl sulfate, dodecyl sulfate ammonium salt, secondary alkane sulfonates, alcohol ethoxylate, acetylenic surfactant, and any combination thereof. Examples of suitable commercially available surfactants include TRITON™, Tergitol™, DOWFAX™ family of surfactants manufactured by Dow Chemicals and various surfactants in SURFYNOL™, DYNOL™, Zetasperse™, Nonidet™, and Tomadol™ surfactant families, manufactured by Air Products and Chemicals. Suitable surfactants of surfactants may also include polymers comprising ethylene oxide (EO) and propylene oxide (PO) groups. An example of EO-PO polymer is Tetronic™ 90R4 from BASF Chemicals.

When employed, the amount of surfactant typically ranges from 0.0001 wt. % to about 1.0 wt. % relative to the total weight of the barrier CMP composition. When employed, the preferred range is from about 0.010 wt. % to about 0.1 wt. %.

### Chelating Agent (Optional)

Chelating agents may optionally be employed in the compositions disclosed herein to enhance affinity of chelating ligands for metal cations. Chelating agents may also be used to prevent build-up of metal ions on pads which causes pad staining and instability in removal rates. Suitable chelating agents include, but are not limited to, for example, amine compounds such as ethylene diamine, amino poly-carboxylic acids such as ethylene diamine tetraacetic acid (EDTA), nitrilotriacetic acid (NTA); aromatic acids such as benzenesulfonic acid, 4-tolyl sulfonic acid, 2,4-diamino-benzosulfonic acid, and etc.; non-aromatic organic acids, such as itaconic acid, malic acid, malonic acid, tartaric acid, citric acid, oxalic acid, gluconic acid, lactic acid, mandelic acid, or salts thereof; various amino acids and their derivatives such as Glycine, Serine, Proline, Histidine, Isoleucine, Leucine, Lysine, Methionine, Phenylalanine, Threonine, Tryptophan, Valine, Arginine, Asparagine, Aspartic acid, cystein, Glutamic acid, Glutamine, Ornithine, Selenocystein, Tyrosine, Sarcosine, Bicine, Tricine, Aceglutamide, N-Acetylaspartic acid, Acetylcarnitine, Acetylcysteine, N-Acetylglutamic acid, Acetylleucine, Acivicin, S-Adenosyl-L-homocysteine, Agaritine, Alanosine, Aminohippuric acid, L-Arginine ethyl ester, Aspartame, Aspartylglucosamine, Benzylmercapturic acid, Biocytin, Brivanib alaninate, Carbocisteine, N(6)-Carboxymethyllysine, Carglumic acid, Cilastatin, Citiolone, Coprine, Dibromotyrosine, Dihydroxyphenylglycine, Eflornithine, Fenclonine, 4-Fluoro-L-threonine, N-Formylmethionine, Gamma-L-Glutamyl-L-cysteine, 4-(γ-Glutamylamino)butanoic acid, Glutaurine, Glycocyamine, Hadacidin, Hepapressin, Lisinopril, Lymecycline, N-Methyl-D-aspartic acid, N-Methyl-L-glutamic acid, Milacemide, Nitrosoproline, Nocardicin A, Nopaline, Octopine, Ombrabulin, Opine, Orthanilic acid, Oxaceprol, Polylysine, Remacemide, Salicyluric acid, Silk amino acid, Stampidine, Tabtoxin, Tetrazolylglycine, Thiorphan, Thymectacin, Tiopronin, Tryptophan tryptophylquinone, Valaciclovir, Valganciclovir, and phosphonic acid and its derivatives such as, for example, octylphosphonic acid, aminobenzylphosphonic acid, and combinations thereof and salts thereof.

Chelating agents may be employed where there is a need to chemically bond, for example, copper cations and tantalum cations to accelerate the dissolution of copper oxide and tantalum oxide to yield the desirable removal rates of copper lines, vias, or trenches and barrier layer, or barrier films.

When employed, the amount of chelating agent preferably ranges from about 0.01 wt. % to about 3.0 wt. % relative to the total weight of the composition and, more preferably, from about 0.4 wt. % to about 1.5 wt. %.

### Biocide (Optional)

CMP formulations disclosed herein may also comprise additives to control biological growth such as biocides. Some of the additives to control biological growth are disclosed in U.S. Pat. No. 5,230,833 and U.S. patent application Publication No. 2002/0025762, which is incorporated herein by reference. Biological growth inhibitors include but are not limited to tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms, sodium chlorite, sodium hypochlorite, isothiazolinone compounds such as methylisothiazolinone, methylchloroisothiazolinone and benzisothiazolinone. Some of the commercially available preservatives include KATHON™ and NEOLENE™ product families from Dow Chemicals and Preventol™ family from Lanxess.

The preferred biocides are isothiozilone compounds such as methylisothiazolinone, methylchloroisothiazolinone and benzisothiazolinone.

The CMP polishing compositions optionally contain a biocide ranging from 0.0001 wt. % to 0.10 wt. %, preferably from 0.0001 wt. % to 0.005 wt. %, and more preferably from 0.0002 wt. % to 0.0025 wt. % to prevent bacterial and fungal growth during storage.

Compositions disclosed herein may be manufactured in a concentrated form and subsequently diluted at the point of use with DI water. Other components such as, for example, the oxidizer, may be withheld in the concentrate form and added at the point of use to minimize incompatibilities between components in the concentrate form. The compositions disclosed herein may be manufactured in two or more components which can be mixed prior to use.

### WORKING EXAMPLES

### General Experimental Procedure

All percentages are weight percentages unless otherwise indicated.

### Part I Synthesis of Cationic-Modified Water-Soluble Polysaccharides

All polysaccharides used in this study are commercially available polymers. The modification of the polymer can be performed by adding the cation to the polymer backbone. The amount of modification (ion density) can be controlled by the amount of modifier added in the reaction or by the type of ion precursor used (the precursor may contain more than one ion).

1-(2-Hydroxyethyl)-3-methylimidazolium chloride was purchased from Holland Moran (15 Avraham Giron St., Yehud-Monosson, Israel). The other reagents and dry solvents were purchased from Sigma-Aldrich (3 Plaut St., Rehovot, Israel). All AR grade solvents were purchased from Bio-Lab (22 HaYettsira St., Jerusalem, Israel). All chemicals of highest commercial grade were used as received unless otherwise specified.

All reactions using dextran can be performed using pectin, inulin or pullulan. All reactions done with phosphonium salts can be done with ammonium salts.

### Example 1: Chitosan-Triphenylphosphonium Bromide Salt—Amine Reaction

### Chitosan Modification:

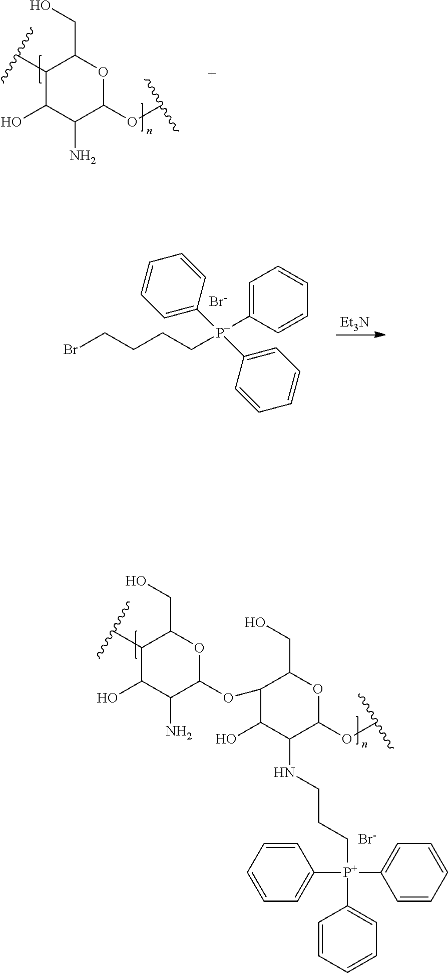

4.0 g of chitosan (50-190 kDa) was dissolved in 200 mL DI water at 75 °C for ~1 hour in a flask. The solution was cooled to room temperature and 17.3 mL of triethylamine were injected into the flask. The mixture was stirred at room temperature for 5 minutes. Then, 23.77 g of (4-bromobutyl)triphenylphosphanium bromide were added with 100 mL acetonitrile. The reaction mixture was then heated back to 70 °C for 48 hours.

After cooling to room temperature, solid precipitated from the solution. The solid was filtered and washed with water, tetrahydrofuran (THF) and dichloromethane (DCM) and dried under vacuum overnight. Ion density was 10-15% (NMR).

### Example 2: Dextran-Triphenylphosphonium Bromide Salt—Hydroxyl Reaction

### Dextran Modification:

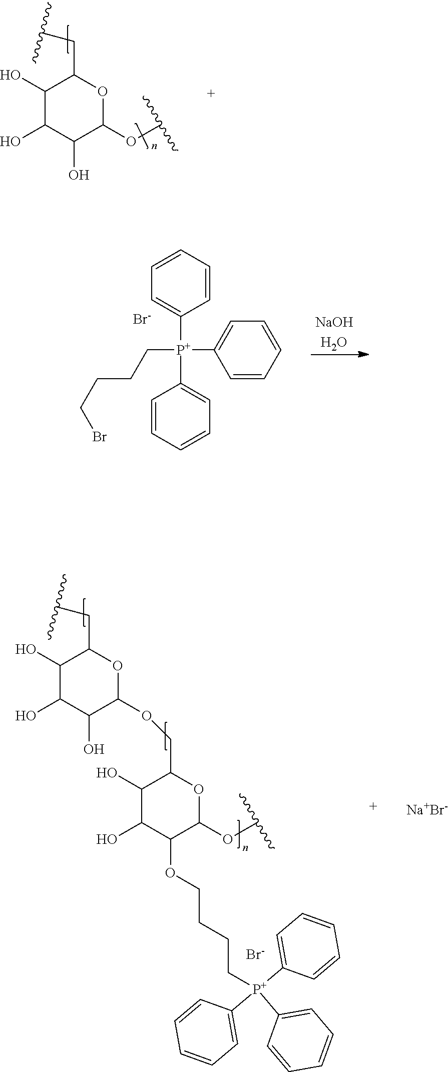

0.5 g of dextran and 3.74 g NaOH were dissolved in 20 mL DI water at room temperature. The mixture was stirred at room temperature for few minutes and then was heated to 70 °C. After 3 hours, the solution was cooled to room temperature, and 4.44 g of (4-bromobutyl)triphenylphosphanium bromide were added with 10 mL acetonitrile. The reaction mixture was then heated back to 70 °C for 24 hours.

After cooling to room temperature, 15 mL of HBr solution 1M were added until pH=6-7. The solvents were evaporated using evaporator and the white solid was extracted with ~100 mL water. The water was then evaporated again, and the resulting solid was extracted with DCM. The DCM phase was discarded, and the white solid was dried under vacuum overnight. Ion density was ~10% (NMR).

### Example 3: Chitosan-Imidazolium Chloride Salt—Imidazolium Modification Through Tosylation

### Tosylated Imidazolium (Ts-Imidazolium) Preparation:

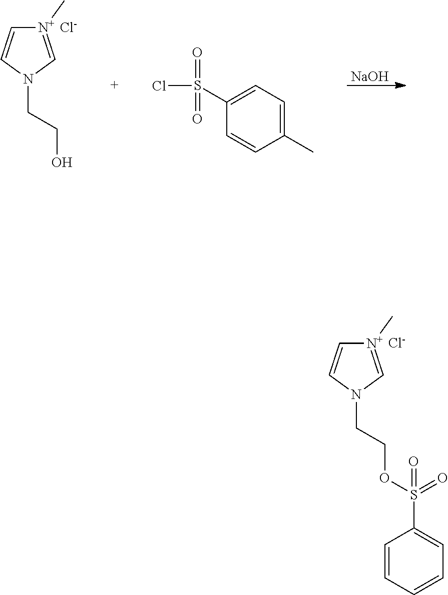

In 150 mL round bottom flask, 3.0 g of hydroxyethyl methylimidazolium chloride was dissolved in 30 mL dimethylformamide (DMF) (heating to ~50 °C was required to dissolve then cooled down to room temperature) under Ar atmosphere. Then the flask was cooled to 0 °C (using ice bath) and 3 mL of pyridine was injected.

30 mL solution of TsCl (5.2 g) in THF was placed in pressure equalizing funnel and was added dropwise during ~30 minutes under cooling. White solid appeared as the dropping persisted. The reaction mixture was heated to 65 °C for 24 hours. When the temperature reached ~50 °C the solid dissolve back into the solution. The solution color changed to yellow and then to dark green.

The reaction mixture was cooled down to room temperature. The mixture was concentrated using evaporator and was passed through column chromatography (silica, chloroform as eluent and then EtOH to extract the product+pyridine).

### Second Stage—Polymer Modification:

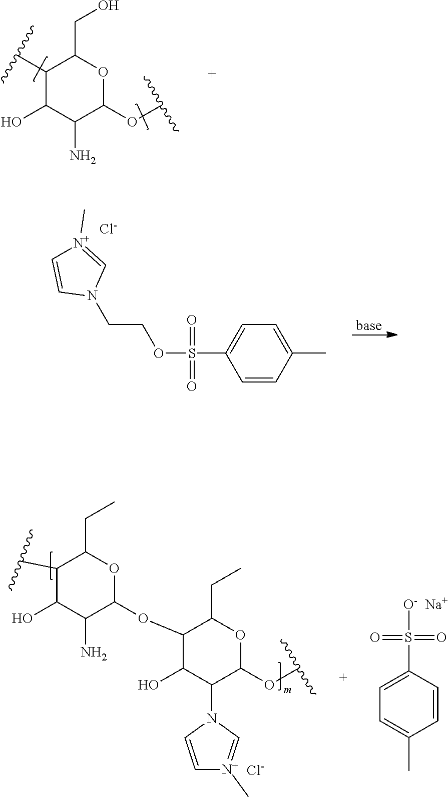

0.756 g of chitosan, 0.975 g NaOH and 2.951 g of Ts-imidazolium chloride were dissolved with 45 mL DI water and 15 mL EtOH. The solution was viscous and at ~50 °C became less viscous. The reaction mixture was heated to 75 °C for 24 hours. The solution became dark brown. The base was neutralized by adding ~17 mL HCl 1.2M. The solvent was evaporated. The polymer was mixed with 75 mL EtOH at room temperature overnight. The brown solid was filtered and dried under vacuum. Ion density was ~70-80% (NMR).

### Example 4: Dextran-(2-hydroxy) propyl-triphenylphosphonium chloride Salt—Modification Using Epichlorohydrine (Prophetic)

Dextran is dissolved in deionized water and a mixture of epichlorohydrine and triphenylphosphine is added. The solution is mixed for 6 hours at 70 °C. The polymer is precipitated with acetone several times and dialyzed against 0.1M HCl and water.

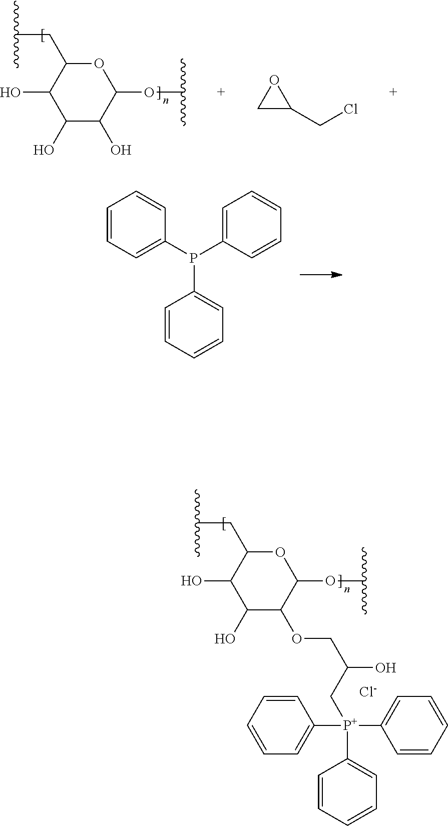

### Example 5: Pectin-Ethylene Diamine Triphenylphosphonium Bromide Salt—Modification by Amidization of Pectin (Prophetic)

At the first stage the pectin is hydrolyzed to the acid counterpart using the following procedure: pectin (PT) is dissolved in aqueous NaOH solution (PT:NaOH molar ratio 1:1). The solution is heated to 50 °C for 24 hours. The solid is precipitated from ethanol and dried using lyophilizer.

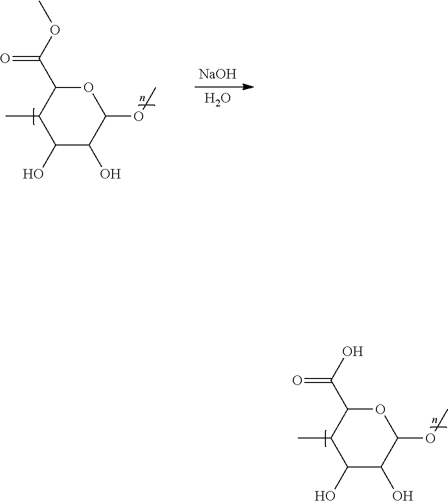

At the second stage the hydrolyzed pectin is aminated to form PT-NH₂ using the following procedure: 2 wt. % aqueous solution of hydrolyzed PT is prepared. Then, ethylene diamine is added (carboxy groups of PT:ethylene diamine molar ratio 1:50) with stirring. The pH is adjusted to be 5 using HCl 0.2M. An aqueous solution of 1-ethyl-3-[3-dimethyl aminopropyl]carbodiimide (EDC) (carboxy groups of PT:EDC molar ratio 1:18) is added to the PT solution. The mixture is mixed at room temperature for 24 hours. The PT-NH₂ is precipitated from ethanol and extracted using Soxhlet with ethanol for 12 hours.

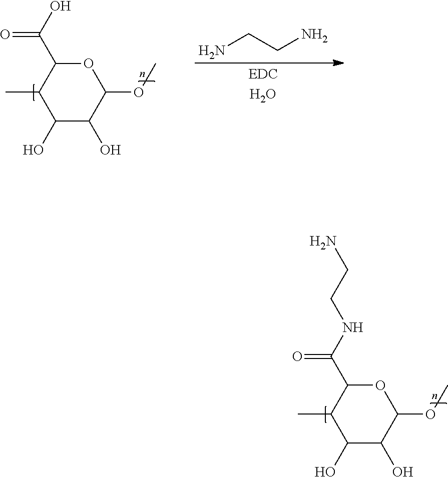

At the third stage the aminated pectin is added with the ion pendent using the procedure of Working example 1.

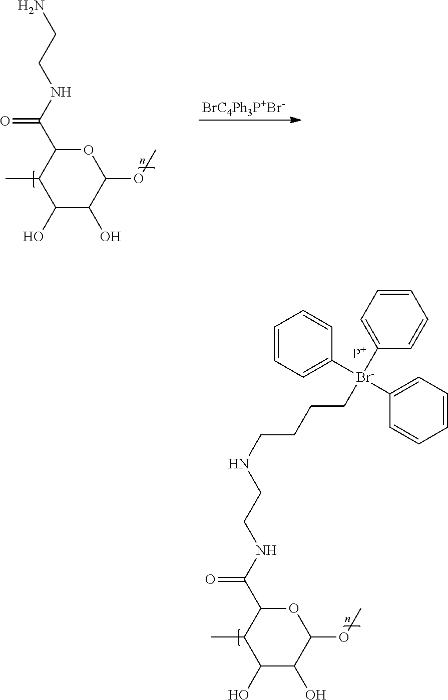

### Example 6: Chitosan-Trialkylphosphonium Bromide Salt (Prophetic)

### Bromoalkyl Phosphonium Synthesis (R can be Alkyl or Benzyl)

First stage—Trialkylphosphine is dissolved with acetonitrile in a round-bottomed flask with stir bar. Dibromoethane dissolved with acetonitrile is added dropwise to the stirring solution. The resulting solution was heated at 65 °C for 48 h and then subsequently concentrated in vacuo. The material was purified using column chromatography (silica, DCM/MeOH).

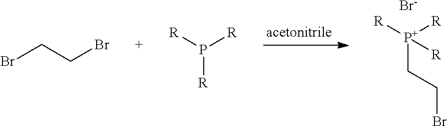

Second stage—chitosan modification: similar to Working Example 1.

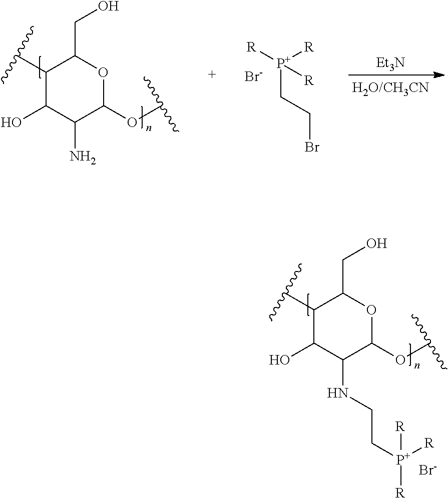

### Example 7: Dextran-Trialkylphosphonium Bromide Salt (Prophetic)

Similar to Working Example 2 (R can be alkyl or benzyl).

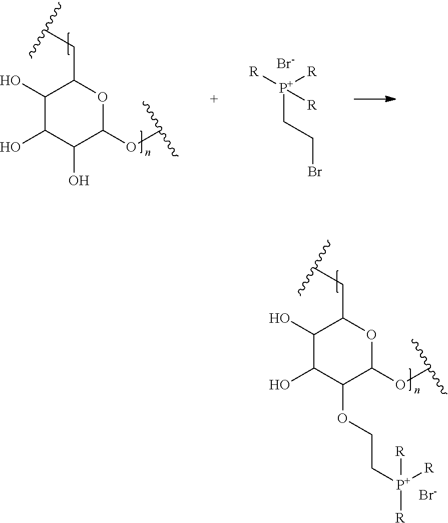

### Example 8: Dextran-Imidazolium Chloride Salt (Prophetic)

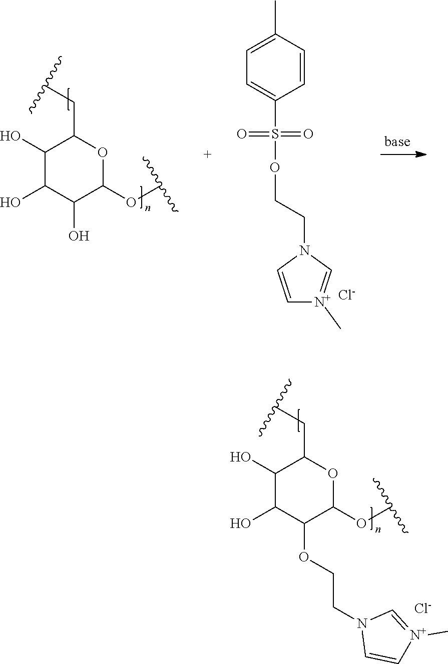

The reaction similar to Working Example 3.

### Example 9: Pectin-Ethylene Diamine Triphenylphosphonium Bromide Salt (Prophetic)

### Amino Phosphonium Synthesis (R can be Alkyl or Benzyl)

First step-alkylphosphine is dissolved in acetonitrile and 2-aminoethyl bromide is added. The reaction mixture is allowed to react for 1.5 h at 25 °C followed by 20 h under reflux under stirring. The temperature is decreased to 25 °C and the solvent is removed by evaporation at 60 °C under reduced pressure. The residue obtained is dissolved in water and the pH value is adjusted to 11 by addition of a saturated aqueous solution of Na₂CO₃. The aqueous system is extracted with dichlormethane. The combined organic phases are dried over MgSO₄, concentrated after removal of the drying agent, and dried. Further purification is done by column chromatography.

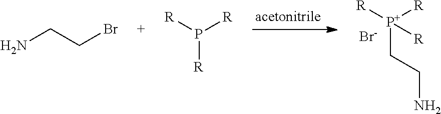

Second step similar to working example 5.

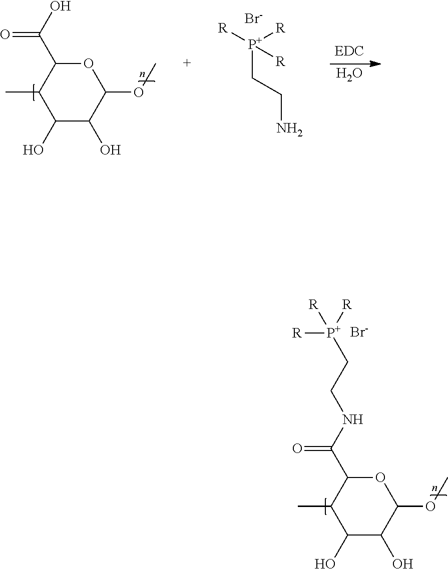

### Example 10: Chitosan-Ethylene Guanidinium Bromide Salt (Prophetic)

First step—Guanidine preparation—A two-necked flask is charged with dry 1,2-dichloroethane and tetramethylurea. Oxalyl chloride is added at room temperature, and the solution is heated for 2 h at 60 °C. The solvent is removed under vacuum, the residual yellow solid is dissolved in 20 mL of dry ethanol. Solution of 33 wt. % methylamine in dry ethanol is added dropwise at 0 °C. The reaction mixture is allowed to warm slowly to room temperature, to stir overnight, and then it is refluxed for 4 h. The solvent is evaporated under vacuum, and the residue is treated with 30% aqueous NaOH. The organic layer is extracted with ether and dried over anhydrous magnesium sulfate. The solvent is then evaporated. The final material is distilled under reduced pressure at 100 °C.

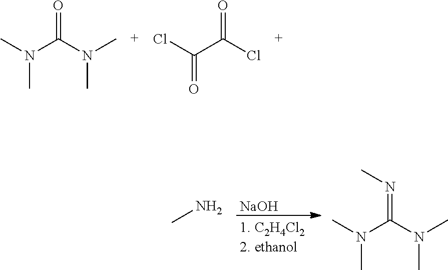

Second step—Similar to first step at Working Example 6.

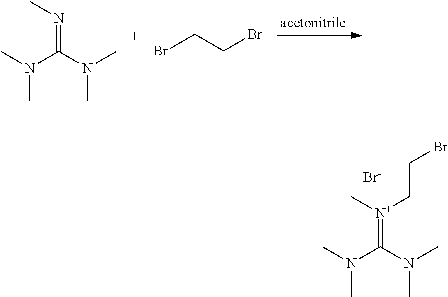

Third step—Similar to Working example 1.

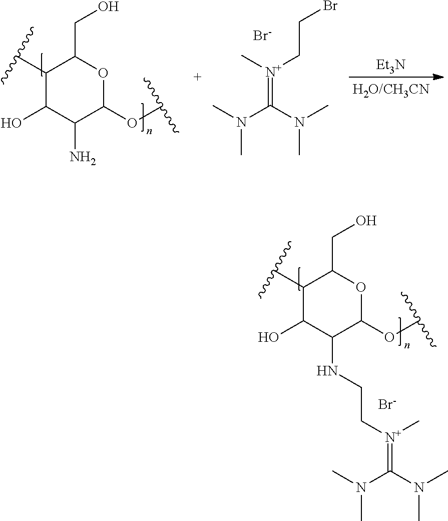

### Example 11: Dextran-Ethylene Guanidinium Bromide Salt (Prophetic)

Similar to Working Example 2.

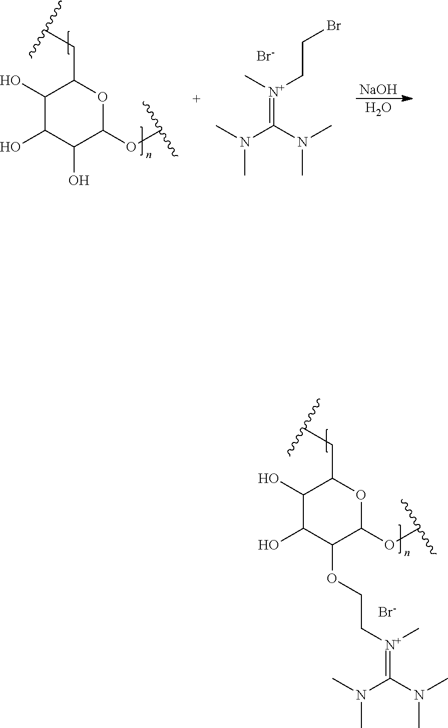

### Example 12: Chitosan-Triazolium Iodide Salt (Prophetic)

First stage-alkyl triazolium salt: 1H-1,2,3 triazole-1-ethanol is dissolved in acetonitrile. Methyl iodide solution in acetonitrile is added dropwise. The reaction is heated to 70 °C for 30 h with continuous stirring. Then, the reaction mixture is washed with ether and is dried in a vacuum oven at room temperature.

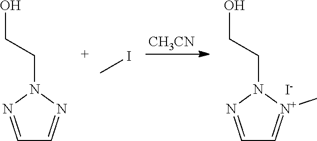

Second stage—Similar to Working Example 3.

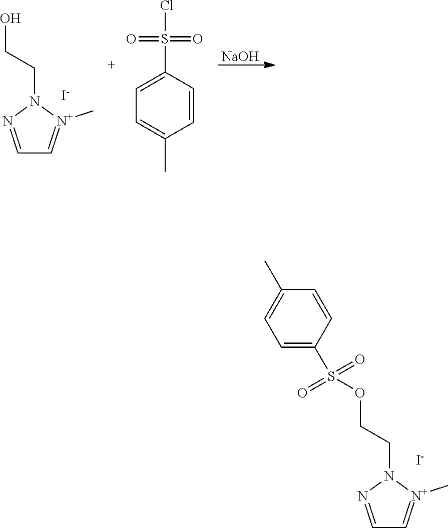

Third step—Similar to Working Example 3.

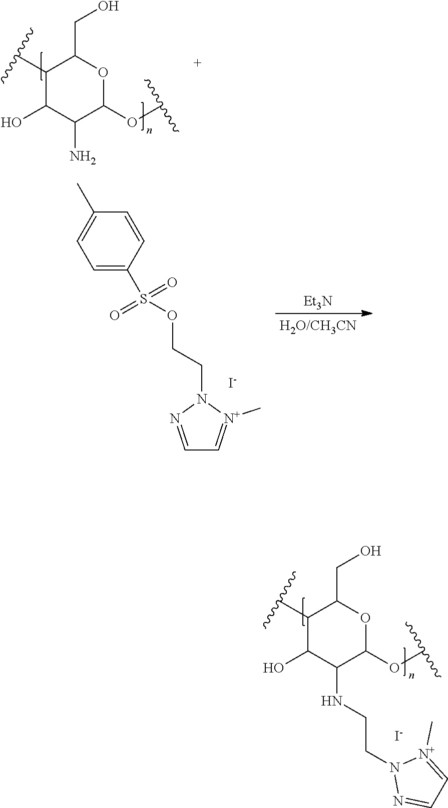

### Example 13: Dextran-Triazolium Iodide Salt (Prophetic)

Similar to Working Example 3.

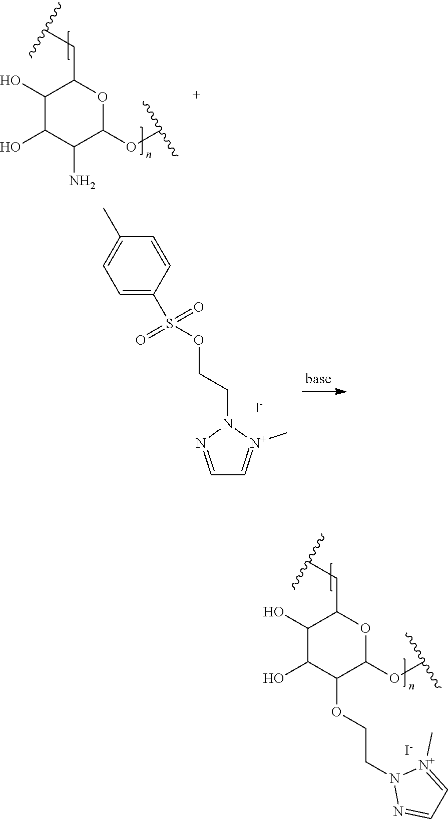

### Example 14: Chitosan-Guanidinium-Triazolium Salt (Prophetic)

First step-guanidinium-triazolium salt: similar to Working example 6.

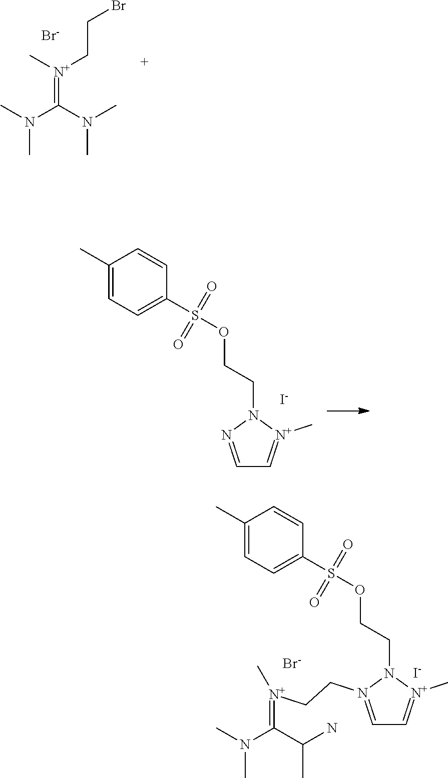

Second step-Chitosan modification: similar to Working Example 3.

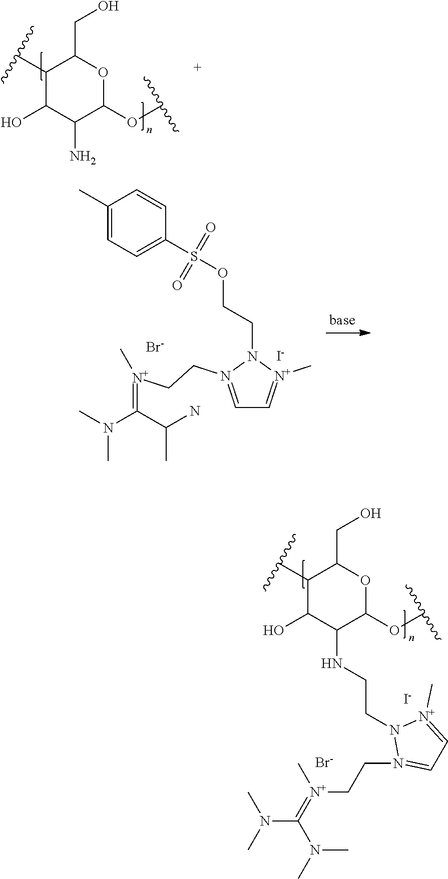

In the same manner other ion pairs can be synthesized.

### Example 15: Dextran-Phosphonium-Triazolium Iodide Salt (Prophetic)

First step—similar to Working Example 6.

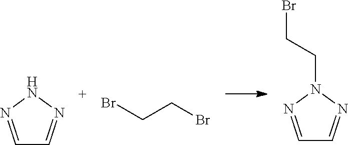

Second step—similar to working example 10 (using bromoethyl alkylphosphonium salt instead of methyl iodide).

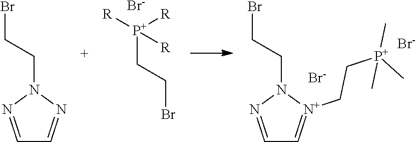

Third step—dextran modification: similar to Working Example 2.

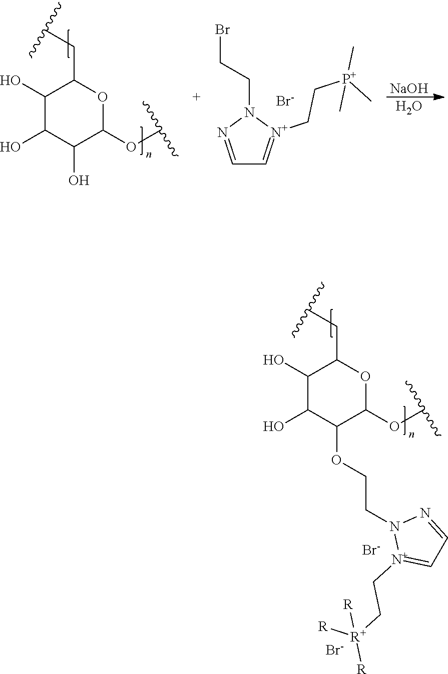

In the same manner other ion pairs can be synthesized.

### Example 16: Chitosan-Trialkylphosphonium/Triphenylphosphonium Mix Bromide (Prophetic)

Similar to working example 1 (R may be 1≤n≤6).

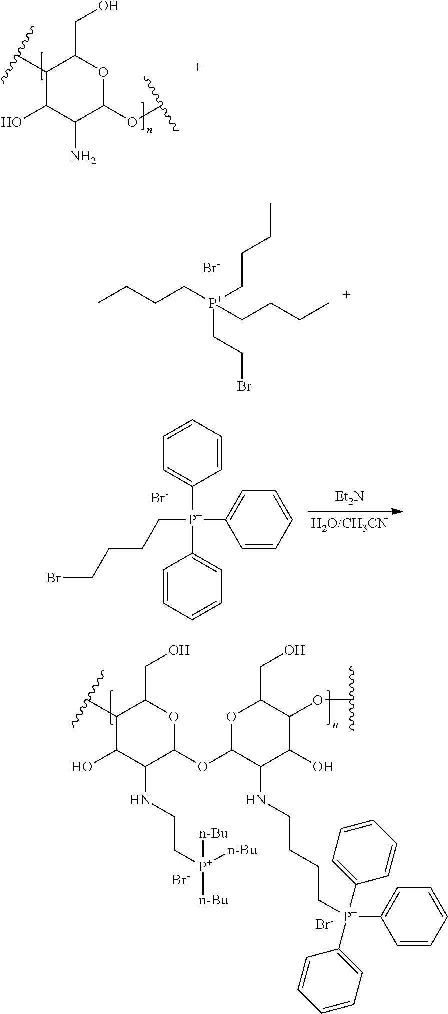

### Example 17: Dextran-Trialkylphosphonium/Triphenylphosphonium Mix Bromide (Prophetic)

Similar to working example 2 (R may be 1≤n≤6).

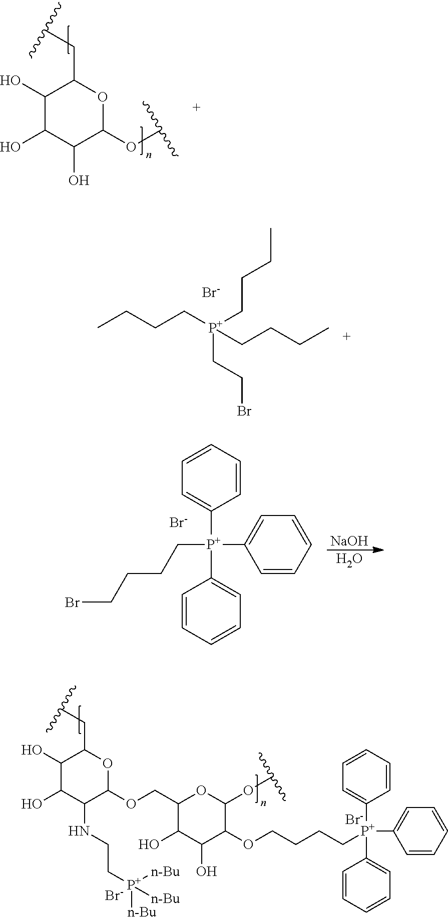

In the same manner other ions mix can be synthesized.

### Part II CMP Experiments

### Using Synthesized Cationic-Modified Water-Soluble Polysaccharide in Part I

The polishing composition and associated methods described herein are effective for CMP of a wide variety of substrates, including most of substrates, particularly useful for polishing tungsten substrates.

In the examples presented below, CMP experiments were run using the procedures and experimental conditions given below.

### Parameters:

Å: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: polishing composition flow, ml/min
TEOS: silicon oxide films by Chemical Vapor Deposition (CVD) using tetraethyl orthosilicate as the precursor
Wt. %: weight percentage (of a listed component)
Removal Rate (RR)=(film thickness before polishing−film thickness after polishing)/polish time.
Removal Rates and Selectivity
Tungsten Removal Rates: Measured tungsten removal rate at 2.5 psi down pressure of the CMP tool.
TEOS Removal Rates: Measured TEOS removal rate at a given down pressure. The down pressure of the CMP tool was 2.5 or 3 psi.
SiN Removal Rates: Measured SiN removal rate at a given down pressure. The down pressure of the CMP tool was 2.5 or 3 psi.

The CMP tool that was used in the examples is a AMAT 200 mm Mirra®, manufactured by Applied Materials, Inc. 3050 Bowers Avenue, Santa Clara, California, 95054. IC1010 polishing pad, supplied by Dow Chemicals was used on the platen for the polishing studies.

200 mm diameter silicon wafers coated with tungsten films, TEOS films, SiN films or tungsten containing SKW patterned structures were obtained from SKW Associate, Inc. 2920 Scott Blvd, Santa Clara, CA 95054. Polish time for blanket films was one minute. Tungsten removal rates were measured using sheet resistance measurement techniques. TEOS removal was measured using optical techniques. Patterned wafers were polished for time based on eddy current technique on the Ebara polisher. Polishing time for patterned wafer was 15 seconds past the end point identified by the eddy current end point technique. Patterned wafers were analyzed with a KLA Tencor P15 Profiler (large feature sizes) or an AFM tool (small feature sizes).

The polishing was performed using 111 RPM table speed, 113 RPM carrier speed, 200 ml/min slurry flow rate and at 2.5 psi downforce.

In the polishing process, a substrate (e.g., blanket W or patterned W wafers) was placed face-down on a polishing pad which was fixedly attached to a rotatable platen of a CMP polisher. In this manner, the substrate to be polished and planarized was placed in direct contact with the polishing pad. A wafer carrier system or polishing head was used to hold the substrate in place and to apply a downward pressure against the backside of the substrate during CMP processing while the platen and the substrate were rotated. The polishing composition (slurry) was applied (usually continuously) on the pad during CMP processing for effective removal of material and planarizing the substrate.

In the following working examples, a CMP base slurry comprising 0.01 wt. % ferric nitrate (iron (III) nitrate), 0.08 wt. % malonic acid (stabilizer), 2.0 wt. % hydrogen peroxide, 0.1 wt. % glycine and 0.25 wt. % surface modified silica particles in water with pH adjusted to 2.3 with nitric acid was prepared.

The surface modified silica particles used in Tables 1 and 2 had an average primary particle size (d1) of 69.77 nm and an average secondary particle size (d2) of 89.7 nm measured using DLS analysis method (Dynamic Light Scattering). The surface modified silica particles were disclosed in U.S. provisional application 63/269,585 filed on Mar. 18, 2022, which are entirely incorporated herein by reference.

The surface modified silica particles used in Tables 3 to 7 were Fuso PL-2C manufactured by Fuso Chemical Corporation having an average primary particle size (d1) of about 20 nm, and an average secondary particle size (d2) of about 40 nm measured using DLS analysis method (Dynamic Light Scattering).

Different amount of the cationic-modified water-soluble polysaccharides synthesized in working Examples 1 and 3 were added to the base slurry as shown in Table 1.

Effects of cationic-modified water-soluble polysaccharides on tungsten, TEOS and SiN removal rates, and W Dishing (50×50 μm) and Erosion (7×3 μm) on patterned wafers were tested using slurries containing inhouse silica particles. The results were summarized in Tables 1 and 2.

TABLE 1
Film Removal Rates and Film Selectivity

| | W RR | TEOS RR | W/TEOS |
|---|---|---|---|
| Sample | (Å/min) | (Å/min) | selectivity |
| Base (no additive) | 3041 | 44 | 31 |
| Example 1, 20 ppm | 3870 | 14 | 276 |
| Example 1, 40 ppm | 3381 | 16 | 211 |
| Example 3, 20 ppm | 4123 | 15 | 275 |

TABLE 2
W Dishing (50 × 50 μm) and Erosion (7 × 3 μm)

| | W Line Dishing | Erosion |
|---|---|---|
| Sample | 50 × 50 μm (Å) | (7 × 3 μm) (Å) |
| Base (no additive) | 3041 | 221 |
| Example 1, 20 ppm | 815 | 239 |
| Example 1, 40 ppm | 310 | 141 |
| Example 3, 20 ppm | 956 | 403 |

As shown in Table 1, surprisingly, CMP slurries using cationic-modified water-soluble polysaccharides increased the RR of W while suppressed the RR of TEOS thus greatly increased the removal selectivity of W: TEOS.

As shown in Table 2, CMP slurries using cationic-modified water-soluble polysaccharides reduced W dishing greatly.

The effects of the concentrations of chitosane-triphenylphosphonium bromide salt (Example 1 polymer additive) on TEOS film removal rates was tested and the results were listed in Table 3.

TABLE 3
Conc. Effects of Example 1 Polymer Additive on W RR (Å/min)

| Sample | WRR (Å/min) |
|---|---|
| Base (no additive) | 2763 |
| Example 1, 10 ppm | 3817 |
| Example 1, 50 ppm | 3715 |
| Example 1, 100 ppm | 2500 |

As the results shown in Table 3, chitosane-triphenylphosphonium bromide salt, when used at 10 ppm or 50 ppm respectively, W film removal rates were increased by 38% and 34% respectively. When it was used at 100 ppm concentration at point of use, the W film removal rate was reduced by about 10%.

Effects of cationic-modified water-soluble polysaccharides on tungsten TEOS and SiN removal rates, and W Dishing (50×50 μm) and Erosion (7×3 μm) on patterned wafers were tested. The results were summarized in Tables 4 and 5.

TABLE 4
Film Removal Rates and Film Selectivity

| | | TEOS | | | |
|---|---|---|---|---|---|
| | W RR | RR | SiN RR | W:TEOS | W:SIN |
| Sample | (Å/min) | (Å/min) | (Å/min) | selectivity | selectivity |
| Base (no additive) | 2763 | 34 | 32 | 81 | 86 |
| Example 3, 20 ppm | 2454 | 35 | 28 | 70 | 88 |
| Example 3, 40 ppm | 2433 | 42 | 27 | 58 | 90 |

TABLE 5
W Dishing (50 × 50 μm) and Erosion (7 × 3 μm)

| | W Line Dishing | Erosion |
|---|---|---|
| Sample | 50 × 50 μm (Å) | (7 × 3 μm) (Å) |
| Base (no additive) | 1177 | 505 |
| Example 3, 20 ppm | 818 | 400 |
| Example 3, 40 ppm | 731 | 405 |

As shown in Table 4, CMP slurries using cationic-modified water-soluble polysaccharides maintained the RR of W, the RR of TEOS or the removal selectivity of W: TEOS.

As shown in Table 5, CMP slurries using cationic-modified water-soluble polysaccharides reduced W dishing greatly. Erosion was improved as well.

The cationic polymer additive in Example 3 was also tested at two concentrations of 15 ppm and 30 ppm, respectively.

The results for tungsten TEOS and SiN removal rates, W Dishing (50×50 μm), and Erosion (7×3 μm) on patterned wafers were summarized in Tables 6 and 7.

TABLE 6
Film Removal Rates and Film Selectivity

| | | TEOS | SiN | | |
|---|---|---|---|---|---|
| | W RR | RR | RR | W/TEOS | W/SiN |
| Sample | (Å/min) | (Å/min) | (Å/min) | selectivity | selectivity |
| Base (no additive) | 2359 | 47 | 30 | 50 | 79 |
| Example 3, 15 ppm | 2484 | 48 | 31 | 52 | 80 |
| Example 3, 30 ppm | 2528 | 48 | 31 | 53 | 82 |

Similar to the data shown in Table 4, CMP slurries using cationic-modified water-soluble polysaccharides maintained the RR of W, the RR of TEOS or the removal selectivity of W: TEOS.

TABLE 7
W Dishing (50 × 50 μm) and Erosion (7 × 3 μm)

| | W Line Dishing | Erosion |
|---|---|---|
| Sample | 50 × 50 μm (Å) | (7 × 3 μm) (Å) |
| Base (no additive) | 1357 | 528 |
| Example 3, 15 ppm | 950 | 408 |
| Example 3, 30 ppm | 888 | 350 |

Similar to the data shown in Table 5, CMP slurries using cationic-modified water-soluble polysaccharides reduced W dishing greatly. Erosion was improved as well.

While the principles of the invention have been described above in connection with preferred embodiments, it is to be clearly understood that this description is made only by way of example and not as a limitation of the scope of the invention. Rather, the ensuing detailed description of the preferred exemplary embodiments will provide those skilled in the art with an enabling description for implementing the preferred exemplary embodiments of the invention. Various changes may be made in the function and arrangement of elements without departing from the spirit and scope of the invention, as set forth in the appended claims.

1. A cationic-modified water-soluble polysaccharide comprising cationic repeating unit having a structure selected from the aroun consisting of 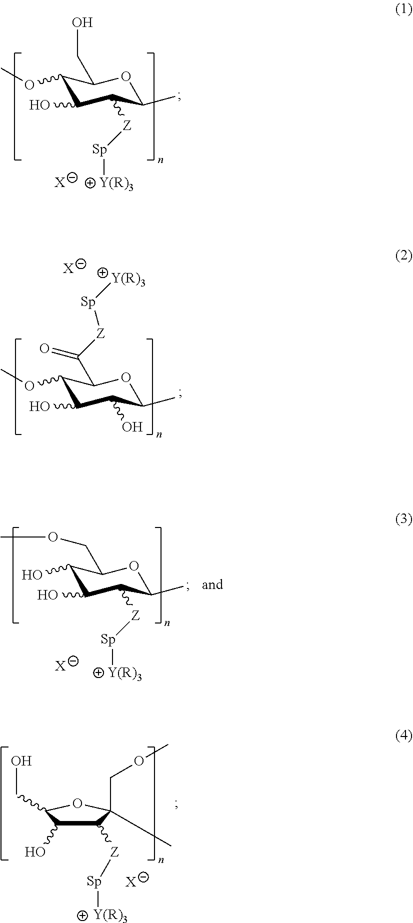
wherein
the water-soluble polysaccharide is selected from the group consisting of chitosan, pectin, dextran, pullulan, and inulin;
pentagon or hexagon denotes the backbone of the water-soluble polysaccharide;
Z is selected from the group consisting of NH, —O—, —S—, —O—(C═O)—, —NH—(C═O)—, —O—(C═O)—, —NH—(C═O)—, NR′ herein R′ is alkyl having C₁ to C₆, and carbon to carbon double-bond or triple-bond as shown below:
—HC═CH—
—R″C═CH—
—R″C═CR″—
R″C═CR′″—
—C≡C—
wherein two carbon atoms in the double bond structure can be connected to two protons, one proton and one alkyl group R″ wherein R″ is alkyl having C₁ to C₆, two same alkyl groups as in R″, or two different alkyl groups as in R″ and R′″ wherein R″ is alkyl having C₁ to C₆;
Sp denotes at each occurrence a spacer group having single bond or double bond structure;
Y⁺ denotes a cation function selected from the group consisting of N⁺, P⁺, and S⁺;
wherein the cationic-modified water-soluble polysaccharides comprises repeating unit containing no ion or at least one ion;
X⁻ denotes the counter ion selected from the group consisting of F⁻, Cl⁻, Br⁻, I⁻, BF₄⁻, CF₃BF₃⁻, OH⁻, PF₆⁻, carboxylate, malonate, citrate, carbonate, fumarate, MeOSO₃⁻, MeSO₃⁻, CF₃COO⁻, CF₃SO₃⁻, cyanate, isothiocyanate, nitrate, phosphate, and sulfate, wherein Me is methyl;
R denotes a cation side group selected from the group consisting of H; CH₃; saturated or unsaturated, branched or aliphatic alkyl chain; cyclic ring, and other functional group selected from the group consisting of amine, carboxylic acid, sulfonate, siloxane, ether, and alcohol; wherein (R)₃ can be alkyl or form a ring selected from the group consisting of imidazolium, triazolium, and tetrazolium; tris-alkyl phosphonium, tris-phenyl phosphonium, tris-alkyl sulfonium, and tris-phenyl sulfonium; and
n denotes the number of the repeating units, wherein 1<n<2000, or 75<n<1000.

2. The cationic-modified water-soluble polysaccharide of claim 1, wherein the water-soluble polysaccharide is modified by a method selected from the group consisting of etherification; esterification; amidation; and amination; and the cationic-modified water-soluble polysaccharide has an ion density between 5-200%, or between 10%-100%.

3. (canceled)

4. The cationic-modified water-soluble polysaccharide of claim 1, wherein the cationic-modified water-soluble polysaccharide is selected from the group consisting of chitosan-triphenylphosphonium bromide salt, dextran-triphenylphosphonium bromide salt, chitosan-imidazolium chloride salt, dextran-(2-hydroxy) propyl-triphenylphosphonium chloride salt, pectin-ethylene diamine triphenylphosphonium bromide salt, chitosan-trialkylphosphonium bromide salt, dextran-trialkylphosphonium bromide salt, pectin-ethylene diamine triphenylphosphonium bromide salt, chitosan-ethylene guanidinium bromide salt, dextran-imidazolium chloride salt, dextran-ethylene guanidinium bromide salt, chitosan-triazolium iodide salt, dextran-triazolium iodide salt, chitosan-guanidinium-triazolium salt, dextran-phosphonium-triazolium iodide salt, chitosan-trialkylphosphonium/triphenylphosphonium mix bromide, dextran-trialkylphosphonium/triphenylphosphonium mix bromide, and combinations thereof.

5. A chemical mechanical planarization composition comprising 0.00001 wt. % to 1.0 wt. % or 0.00025 wt. % to 0.1 wt. % of the cationic-modified water-soluble polysaccharide of claim 1; and the cationic-modified water-soluble polysaccharide has an ion density between 5-200% or between 10%-100%.

6. The chemical mechanical planarization composition of claim 5 further comprising at least one of:
an abrasive;
an activator;
an oxidizing agent;
a corrosion inhibitor;
a dishing reducing agent;
a stabilizer;
a pH adjusting agent.

7. The chemical mechanical planarization composition of claim 6, wherein the abrasive is selected from the group consisting of inorganic oxide particles, metal oxide-coated inorganic oxide particles, organic polymer particles, metal oxide-coated organic polymer particles, and combinations thereof; and the abrasive ranges from 0.01 wt. % to 30 wt. %, or from 0.1 wt. % to 2 wt. %.

8. The chemical mechanical planarization composition claim 6, wherein the cationic-modified water-soluble polysaccharide is selected from the group consisting of chitosan-triphenylphosphonium bromide salt, dextran-triphenylphosphonium bromide salt, chitosan-imidazolium chloride salt, dextran-(2-hydroxy) propyl-triphenylphosphonium chloride salt, pectin-ethylene diamine triphenylphosphonium bromide salt, chitosan-trialkylphosphonium bromide salt, dextran-trialkylphosphonium bromide salt, pectin-ethylene diamine triphenylphosphonium bromide salt, chitosan-ethylene guanidinium bromide salt, dextran-imidazolium chloride salt, dextran-ethylene guanidinium bromide salt, chitosan-triazolium iodide salt, dextran-triazolium iodide salt, chitosan-guanidinium-triazolium salt, dextran-phosphonium-triazolium iodide salt, chitosan-trialkylphosphonium/triphenylphosphonium mix bromide, dextran-trialkylphosphonium/triphenylphosphonium mix bromide, and combinations thereof.

9. (canceled)

10. (canceled)

11. The chemical mechanical planarization composition of claim 6, wherein the activator is selected from the group consisting of (1) inorganic oxide particle with transition metal coated onto its surface; and the transition metal is selected from the group consisting of Fe, Cu, Mn, Co, Ce, and combinations thereof; (2) soluble catalyst selected from the group consisting of iron (III) nitrate, ammonium iron (III) oxalate trihydrate, iron (III) citrate tribasic monohydrate, iron (III) acetylacetonate and ethylenediamine tetraacetic acid, and iron (III) sodium salt hydrate; (3) a metal compound having multiple oxidation states selected from the group consisting of Ag, Co, Cr, Cu, Fe, Mo, Mn, Nb, Ni, Os, Pd, Ru, Sn, Ti, and V; and combinations thereof;
the oxidizing agent is selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, and ammonium peroxymonosulfate;
and non-peroxy compound selected from the group consisting of ferric nitrite, KClO₄, KBrO₄, and KMnO₄; and combinations thereof;
the corrosion inhibitor is selected from the group consisting of 1,2,3-triazole, 1,2,4-triazole, 1,2,3-benzotriazole, 5-methylbenzotriazole, benzotriazole, 1-hydroxybenzotriazole, 4-hydroxybenzotriazole, 3-amino-1,2,4-triazole, 4-amino-4H-1,2,4-triazole, 5 amino triazole, benzimidazole, 2,1,3-benzothiadiazole, triazinethiol, triazinedithiol, and triazinetrithiol, pyrazoles, imidazoles, isocyanurate such as 1,3,5-Tris(2-hydroxyethyl), and combinations thereof;
the dishing reducing agent is selected from the group consisting of sarcosinate and related carboxylic compounds; hydrocarbon substituted sarcosinate; amino acids; organic polymers and copolymers having molecules containing ethylene oxide repeating units, ethoxylated surfactants; nitrogen containing heterocycles without nitrogen-hydrogen bonds; sulfide; oxazolidine or mixture of functional groups in one compound; nitrogen containing compounds having three or more carbon atoms that form alkylammonium ions; amino alkyls having three or more carbon atoms; polymeric corrosion inhibitor comprising a repeating group of at least one nitrogen-containing heterocyclic ring or a tertiary or quaternary nitrogen atom; polycationic amine compound; cyclodextrin compound; polyethyleneimine compound; glycolic acid; chitosan; sugar alcohols;
polysaccharides; alginate compound; and sulfonic acid polymer; and combinations thereof;
the stabilizer is selected from the group consisting of adipic acid, phthalic acid, citric acid, malonic acid, orthophthalic acid; phosphoric acid; substituted or unsubstituted phosphonic acids; nitriles; and combinations thereof; and
the pH adjusting agent is selected from the group consisting of (a) nitric acid, sulfuric acid, tartaric acid, succinic acid, citric acid, malic acid, malonic acid, various fatty acids, various polycarboxylic acids, and mixtures thereof to lower the pH; and (b) potassium hydroxide, sodium hydroxide, ammonia, tetraethylammonium hydroxide, ethylenediamine, piperazine, polyethyleneimine, modified polyethyleneimine, and mixtures thereof to raise the pH.

12. (canceled)

13. (canceled)

14. (canceled)

15. (canceled)

16. (canceled)

17. The chemical mechanical planarization composition of claim 6, wherein the chemical mechanical planarization composition comprises silica particles or surface modified silica particles; the cationic-modified water-soluble polysaccharide is selected from the group consisting of chitosan-triphenylphosphonium bromide salt, dextran-triphenylphosphonium bromide salt, chitosan-imidazolium chloride salt, dextran-(2-hydroxy) propyl-triphenylphosphonium chloride salt, pectin-ethylene diamine triphenylphosphonium bromide salt, chitosan-trialkylphosphonium bromide salt, dextran-trialkylphosphonium bromide salt, pectin-ethylene diamine triphenylphosphonium bromide salt, chitosan-ethylene guanidinium bromide salt, dextran-imidazolium chloride salt, dextran-ethylene guanidinium bromide salt, chitosan-triazolium iodide salt, dextran-triazolium iodide salt, chitosan-guanidinium-triazolium salt, dextran-phosphonium-triazolium iodide salt, chitosan-trialkylphosphonium/triphenylphosphonium mix bromide, dextran-trialkylphosphonium/triphenylphosphonium mix bromide, and combinations thereof; iron (III) nitrate, malonic acid, hydrogen peroxide, and water; the pH of the composition is between 1 and 14 or 1 and 7.

18. A polishing method for chemical mechanical planarization of a semiconductor substrate comprising at least one surface containing tungsten, comprising the steps of:
a) providing a polishing pad;
b) providing a chemical mechanical planarization composition comprising:
an abrasive;
an additive comprising 0.00001 wt. % to 1.0 wt. % or 0.00025 wt. % to 0.1 wt. % of the cationic-modified water-soluble polysaccharide of claim 1;
water; and optionally at least one of
an activator;
an oxidizing agent;
a corrosion inhibitor;
a dishing reducing agent;
a stabilizer;
a pH adjusting agent;
wherein the cationic-modified water-soluble polysaccharide has an ion density between 5-200%, or between 10%-100%; and
c) polishing the at least one surface containing tungsten with the chemical mechanical planarization composition.

19. The polishing method of claim 18, wherein the chemical mechanical planarization composition has the abrasive selected from the group consisting of inorganic oxide particles, metal oxide-coated inorganic oxide particles, organic polymer particles, metal oxide-coated organic polymer particles, and combinations thereof; and the abrasive ranges from 0.01 wt. % to 30 wt. %, or from 0.1 wt. % to 2 wt. %.

20. The polishing method according to of claim 18, wherein the additive comprising the cationic-modified water-soluble polysaccharide is selected from the group consisting of chitosan-triphenylphosphonium bromide salt, dextran-triphenylphosphonium bromide salt, chitosan-imidazolium chloride salt, dextran-(2-hydroxy) propyl-triphenylphosphonium chloride salt, pectin-ethylene diamine triphenylphosphonium bromide salt, chitosan-trialkylphosphonium bromide salt, dextran-trialkylphosphonium bromide salt, pectin-ethylene diamine triphenylphosphonium bromide salt, chitosan-ethylene guanidinium bromide salt, dextran-imidazolium chloride salt, dextran-ethylene guanidinium bromide salt, chitosan-triazolium iodide salt, dextran-triazolium iodide salt, chitosan-guanidinium-triazolium salt, dextran-phosphonium-triazolium iodide salt, chitosan-trialkylphosphonium/triphenylphosphonium mix bromide, dextran-trialkylphosphonium/triphenylphosphonium mix bromide, and combinations thereof.

21. (canceled)

22. (canceled)

23. The polishing method of claim 18, wherein the activator is selected from the group consisting of (1) inorganic oxide particle with transition metal coated onto its surface; and the transition metal is selected from the group consisting of Fe, Cu, Mn, Co, Ce, and combinations thereof; (2) soluble catalyst selected from the group consisting of iron (III) nitrate, ammonium iron (III) oxalate trihydrate, iron (III) citrate tribasic monohydrate, iron (III) acetylacetonate and ethylenediamine tetraacetic acid, and iron (III) sodium salt hydrate; (3) a metal compound having multiple oxidation states selected from the group consisting of Ag, Co, Cr, Cu, Fe, Mo, Mn, Nb, Ni, Os, Pd, Ru, Sn, Ti, and V; and combinations thereof; the oxidizing agent is selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, and ammonium peroxymonosulfate; and non-peroxy compound selected from the group consisting of ferric nitrite, KClO₄, KBrO₄, and KMnO₄; and combinations thereof;
the corrosion inhibitor is selected from the group consisting of 1,2,3-triazole, 1,2,4-triazole, 1,2,3-benzotriazole, 5-methylbenzotriazole, benzotriazole, 1-hydroxybenzotriazole, 4-hydroxybenzotriazole, 3-amino-1,2,4-triazole, 4-amino-4H-1,2,4-triazole, 5 amino triazole, benzimidazole, 2,1,3-benzothiadiazole, triazinethiol, triazinedithiol, and triazinetrithiol, pyrazoles, imidazoles, isocyanurate such as 1,3,5-Tris(2-hydroxyethyl), and combinations thereof;
the dishing reducing agent is selected from the group consisting of sarcosinate and related carboxylic compounds; hydrocarbon substituted sarcosinate; amino acids; organic polymers and copolymers having molecules containing ethylene oxide repeating units, ethoxylated surfactants; nitrogen containing heterocycles without nitrogen-hydrogen bonds; sulfide; oxazolidine or mixture of functional groups in one compound; nitrogen containing compounds having three or more carbon atoms that form alkylammonium ions; amino alkyls having three or more carbon atoms; polymeric corrosion inhibitor comprising a repeating group of at least one nitrogen-containing heterocyclic ring or a tertiary or quaternary nitrogen atom; polycationic amine compound; cyclodextrin compound; polyethyleneimine compound; glycolic acid; chitosan; sugar alcohols;
polysaccharides; alginate compound; and sulfonic acid polymer; and combinations thereof;
the stabilizer is selected from the group consisting of adipic acid, phthalic acid, citric acid, malonic acid, orthophthalic acid; phosphoric acid; substituted or unsubstituted phosphonic acids; nitriles; and combinations thereof; and
the pH adjusting agent is selected from the group consisting of (a) nitric acid, sulfuric acid, tartaric acid, succinic acid, citric acid, malic acid, malonic acid, various fatty acids, various polycarboxylic acids, and mixtures thereof to lower the pH; and (b) potassium hydroxide, sodium hydroxide, ammonia, tetraethylammonium hydroxide, ethylenediamine, piperazine, polyethyleneimine, modified polyethyleneimine, and mixtures thereof to raise the pH.

24. (canceled)

25. (canceled)

26. (canceled)

27. (canceled)

28. (canceled)

29. The polishing method of claim 18, wherein the chemical mechanical planarization composition comprises silica particles or surface modified silica particles; the cationic-modified water-soluble polysaccharide is selected from the group consisting of chitosan-triphenylphosphonium bromide salt, dextran-triphenylphosphonium bromide salt, chitosan-imidazolium chloride salt, dextran-(2-hydroxy) propyl-triphenylphosphonium chloride salt, pectin-ethylene diamine triphenylphosphonium bromide salt, chitosan-trialkylphosphonium bromide salt, dextran-trialkylphosphonium bromide salt, pectin-ethylene diamine triphenylphosphonium bromide salt, chitosan-ethylene guanidinium bromide salt, dextran-imidazolium chloride salt, dextran-ethylene guanidinium bromide salt, chitosan-triazolium iodide salt, dextran-triazolium iodide salt, chitosan-guanidinium-triazolium salt, dextran-phosphonium-triazolium iodide salt, chitosan-trialkylphosphonium/triphenylphosphonium mix bromide, dextran-trialkylphosphonium/triphenylphosphonium mix bromide, and combinations thereof; iron (III) nitrate; malonic acid; hydrogen peroxide; poly(vinyl-3-ethyl-1H-imidazol-3-ium-co-tributyl-(4-vinylbenzyl)-phosphonium) bromide chloride, and water; the pH of the composition is between 1 and 7 or 1.5 and 4.

30. A system for chemical mechanical planarization of a semiconductor substrate comprising at least one surface containing tungsten, comprising:
a) a polishing pad; and
b) a chemical mechanical planarization composition comprising:
an abrasive;
0.00001 wt. % to 1.0 wt. % or 0.00025 wt. % to 0.1 wt. % of the cationic-modified water-soluble polysaccharide of claim 1;
water; and optionally at least one of
an activator;
an oxidizing agent;
a corrosion inhibitor;
a dishing reducing agent;
a stabilizer;
a pH adjusting agent;
wherein the cationic-modified water-soluble polysaccharide has an ion density between 5-200%, or between 10%-100%; and
wherein the at least one surface containing tungsten is in contact with the polishing pad and the chemical mechanical planarization composition, thereby polishing the at least one surface containing tungsten with the chemical mechanical planarization composition.

31. The system of claim 30, wherein the chemical mechanical planarization composition has the abrasive selected from the group consisting of inorganic oxide particles, metal oxide-coated inorganic oxide particles, organic polymer particles, metal oxide-coated organic polymer particles, and combinations thereof; and the abrasive ranges from 0.01 wt. % to 30 wt. %, or from 0.1 wt. % to 2 wt. %.

32. The system of claim 30, wherein the additive comprising the cationic-modified water-soluble polysaccharide is selected from the group consisting of chitosan-triphenylphosphonium bromide salt, dextran-triphenylphosphonium bromide salt, chitosan-imidazolium chloride salt, dextran-(2-hydroxy) propyl-triphenylphosphonium chloride salt, pectin-ethylene diamine triphenylphosphonium bromide salt, chitosan-trialkylphosphonium bromide salt, dextran-trialkylphosphonium bromide salt, pectin-ethylene diamine triphenylphosphonium bromide salt, chitosan-ethylene guanidinium bromide salt, dextran-imidazolium chloride salt, dextran-ethylene guanidinium bromide salt, chitosan-triazolium iodide salt, dextran-triazolium iodide salt, chitosan-guanidinium-triazolium salt, dextran-phosphonium-triazolium iodide salt, chitosan-trialkylphosphonium/triphenylphosphonium mix bromide, dextran-trialkylphosphonium/triphenylphosphonium mix bromide, and combinations thereof.

33. (canceled)

34. (canceled)

35. The system of claim 30, wherein the activator is selected from the group consisting of (1) inorganic oxide particle with transition metal coated onto its surface; and the transition metal is selected from the group consisting of Fe, Cu, Mn, Co, Ce, and combinations thereof; (2) soluble catalyst selected from the group consisting of iron (III) nitrate, ammonium iron (III) oxalate trihydrate, iron (III) citrate tribasic monohydrate, iron (III) acetylacetonate and ethylenediamine tetraacetic acid, and iron (III) sodium salt hydrate; (3) a metal compound having multiple oxidation states selected from the group consisting of Ag, Co, Cr, Cu, Fe, Mo, Mn, Nb, Ni, Os, Pd, Ru, Sn, Ti, and V; and combinations thereof; the oxidizing agent is selected from the group consisting of peroxy compound selected from the group consisting of hydrogen peroxide, urea peroxide, peroxyformic acid, peracetic acid, propaneperoxoic acid, substituted or unsubstituted butaneperoxoic acid, hydroperoxy-acetaldehyde, potassium periodate, and ammonium peroxymonosulfate; and non-peroxy compound selected from the group consisting of ferric nitrite, KClO₄, KBrO₄, and KMnO₄; and combinations thereof; the corrosion inhibitor is selected from the group consisting of 1,2,3-triazole, 1,2,4-triazole, 1,2,3-benzotriazole, 5-methylbenzotriazole, benzotriazole, 1-hydroxybenzotriazole, 4-hydroxybenzotriazole, 3-amino-1,2,4-triazole, 4-amino-4H-1,2,4-triazole, 5 amino triazole, benzimidazole, 2,1,3-benzothiadiazole, triazinethiol, triazinedithiol, and triazinetrithiol, pyrazoles, imidazoles, isocyanurate such as 1,3,5-Tris(2-hydroxyethyl), and combinations thereof;
the dishing reducing agent is selected from the group consisting of sarcosinate and related carboxylic compounds; hydrocarbon substituted sarcosinate; amino acids; organic polymers and copolymers having molecules containing ethylene oxide repeating units, ethoxylated surfactants; nitrogen containing heterocycles without nitrogen-hydrogen bonds; sulfide; oxazolidine or mixture of functional groups in one compound; nitrogen containing compounds having three or more carbon atoms that form alkylammonium ions; amino alkyls having three or more carbon atoms; polymeric corrosion inhibitor comprising a repeating group of at least one nitrogen-containing heterocyclic ring or a tertiary or quaternary nitrogen atom; polycationic amine compound; cyclodextrin compound; polyethyleneimine compound; glycolic acid; chitosan; sugar alcohols;
polysaccharides; alginate compound; and sulfonic acid polymer; and combinations thereof;
the stabilizer is selected from the group consisting of adipic acid, phthalic acid, citric acid, malonic acid, orthophthalic acid; phosphoric acid; substituted or unsubstituted phosphonic acids; nitriles; and combinations thereof; and
the pH adjusting agent is selected from the group consisting of (a) nitric acid, sulfuric acid, tartaric acid, succinic acid, citric acid, malic acid, malonic acid, various fatty acids, various polycarboxylic acids, and mixtures thereof to lower the pH; and (b) potassium hydroxide, sodium hydroxide, ammonia, tetraethylammonium hydroxide, ethylenediamine, piperazine, polyethyleneimine, modified polyethyleneimine, and mixtures thereof to raise the pH.

36. (canceled)

37. (canceled)

38. (canceled)

39. (canceled)

40. (canceled)

41. The system of claim 30, wherein the chemical mechanical planarization composition comprises silica particles or surface modified silica particles; the cationic-modified water-soluble polysaccharide is selected from the group consisting of chitosan-triphenylphosphonium bromide salt, dextran-triphenylphosphonium bromide salt, chitosan-imidazolium chloride salt, dextran-(2-hydroxy) propyl-triphenylphosphonium chloride salt, pectin-ethylene diamine triphenylphosphonium bromide salt, chitosan-trialkylphosphonium bromide salt, dextran-trialkylphosphonium bromide salt, pectin-ethylene diamine triphenylphosphonium bromide salt, chitosan-ethylene guanidinium bromide salt, dextran-imidazolium chloride salt, dextran-ethylene guanidinium bromide salt, chitosan-triazolium iodide salt, dextran-triazolium iodide salt, chitosan-guanidinium-triazolium salt, dextran-phosphonium-triazolium iodide salt, chitosan-trialkylphosphonium/triphenylphosphonium mix bromide, dextran-trialkylphosphonium/triphenylphosphonium mix bromide, and combinations thereof; iron (III) nitrate; malonic acid; hydrogen peroxide; poly(vinyl-3-ethyl-1H-imidazol-3-ium-co-tributyl-(4-vinylbenzyl)-phosphonium) bromide chloride, and water; the pH of the composition is between 1 and 7 or 1.5 and 4.

42. The chemical mechanical planarization composition of claim 17, wherein the pH of the composition is between 1.5 and 4.
